(19) United States
(12) Patent Application Publication
(10) Pub. No.: US 2024/0125229 A1
(43) Pub. Date: Apr. 18, 2024

(54) Fast Proxy Model For Well Casing Integrity Evaluation

(71) Applicant: Halliburton Energy Services, Inc., Houston, TX (US)

(72) Inventors: Xusong Wang, Singapore (SG); Ahmed Fouda, Spring, TX (US); Xiang Wu, Singapore (SG); Christopher Michael Jones, Katy, TX (US); Wei Zhang, Katy, TX (US); Junwen Dai, The Woodlands, TX (US)

(73) Assignee: Halliburton Energy Services, Inc., Houston, TX (US)

(21) Appl. No.: 17/968,628

(22) Filed: Oct. 18, 2022

(51) Int. Cl. E21B 47/092; E21B 43/25

(52) U.S. Cl. CPC E21B 47/092; E21B 43/25

(57) ABSTRACT

A method and non-transitory storage computer-readable medium for performing a neural operator on one or more wellbore measurements. The method may comprise o obtaining one or more measurements, performing a measurement normalization on the one or more measurements to form one or more normalized measurements, forming a material function with the one or more normalized measurements, and forming a neural operator generated physical response with a neural operator and the material function. The method may further comprise forming a beamforming map with the one or more measurements, and forming a neural operator leak source location map with a neural operator and the one or more measurements.

### BACKGROUND

For oil and gas exploration and production, a network of wells, installations and other conduits may be established by connecting sections of metal pipe together. For example, a well installation may be completed, in part, by lowering multiple sections of metal pipe (i.e., a casing string) into a wellbore, and cementing the casing string in place. In some well installations, multiple casing strings are employed (e.g., a concentric multi-string arrangement) to allow for different operations related to well completion, production, or enhanced oil recovery (EOR) options.

Corrosion of metal pipes is an ongoing issue. Efforts to mitigate corrosion include use of corrosion-resistant alloys, coatings, treatments, and corrosion transfer, among others. To enhance wellbore productivity, it may be valuable to employ corrosion monitoring. Efforts to improve corrosion monitoring are ongoing. For downhole casing strings, various types of corrosion monitoring tools are available. One type of corrosion monitoring tool uses electromagnetic (EM) fields to estimate pipe thickness or other corrosion indicators. As an example, a downhole tool may collect data in the form of magnitude and phase of eddy currents from casing strings to produce an EM log. The EM log data may be interpreted to determine condition and thickness of production and inter mediate casing strings, tubing, collars, filters, packers, and perforations. Traditionally, an inversion algorithm may be used to determine the pipe status. Similarly, the downhole tool may be used in leak source applications to obtain acoustic wavefield vibrations and acoustic wavefield vibrations, which are traditionally used in beamforming. Beamforming is a form of inversion that may be used to determine a leak source in a pipe string.

However, when determining properties, such as corrosion, inversion algorithms fall short of efficiently solving for pipe properties even when using a simplified radial one-dimensional model. Similarly, beamforming algorithms may also fall short for efficiently solving for leak location parameters in a two-dimensional model, even with using high-performance computing or graphic processing unit (GPU). For inversion and beamforming, the traditional bottleneck of efficiency may be identified in the forward model. Additionally, the data has to be sent to remote data center and the 2-D beamforming results or 1-D inversion may only be obtained as a post-processing answer product, which reduces their value for real-time decision-making.

### BRIEF DESCRIPTION OF THE DRAWINGS

These drawings illustrate certain aspects of some examples of the present disclosure and should not be used to limit or define the disclosure.

FIG. 1 illustrates an example of an operating environment for a downhole tool;

FIG. 2 illustrates the downhole tool disposed in a pipe string;

FIG. 3A illustrates an operation of the downhole tool;

FIG. 3B illustrates a graph of a transmitter current and a receiver voltage across a range of phases;

FIG. 4A illustrates one or more high resolution receivers;

FIG. 4B illustrates a near field, a transition zone, and a far field;

FIG. 5 illustrates an example of an operating environment for the downhole tool;

FIG. 6 illustrates an expanded view of a measurement assembly;

FIG. 7 illustrates another example of the downhole tool;

FIG. 8 illustrates a leak source;

FIG. 9 illustrates an example of an information handling system;

FIG. 10 illustrates a chipset architecture utilized in the information handling system;

FIG. 11 illustrates an example of one arrangement of resources in cloud computing network;

FIG. 12 illustrates a machine learning model;

FIG. 13A illustrates a magnetic permeability of a material function;

FIG. 13B illustrates electrical conductivity of material function;

FIG. 13C illustrates combined phase and amplitude;

FIG. 14 illustrates an example physical response with combined phase and amplitude, identified as physical responses;

FIG. 15 illustrates an example of a formed physical responses;

FIG. 16A illustrates traditional beamforming results with a reflected acoustic wave;

FIG. 16B illustrates a velocity model;

FIG. 17 illustrates an FNO or PINO operator;

FIG. 18 illustrates different dimensions of inputs and outputs to the neural operator;

FIG. 18 illustrates coarse grids and dense grids;

FIG. 19 illustrates a workflow, a traditional (partial differential equation) PDE numerical forward modeling to map the material function to the physical response;

FIG. 20 illustrates workflow, an FNO or PINO substitution of the forward modeling to map material function to physical response;

FIG. 21 illustrates a workflow, an FNO or PINO substituting the forward modeling to map physical response to material function;

FIG. 22 illustrates a workflow, an FNO or PINO inversion for pipe inspection;

FIG. 23 outlines a workflow, a simplified FNO or PINO inversion for pipe inspection;

FIG. 24 illustrates a workflow, for an FNO or PINO substitution for traditional forward modeling to map reflected acoustic wave;

FIG. 25 illustrates a workflow, for an FNO or PINO inversion with a known velocity model for leak source location;

FIG. 26 illustrates a workflow, for an FNO or PINO inversion for leak source location without a known velocity model; and

FIG. 27 illustrates a workflow, for a simplified FNO or PINO inversion for leak source location;

### DETAILED DESCRIPTION

The present disclosure relates to subterranean operations and, more particularly, embodiments disclosed herein provide methods and systems for improving efficiency for solving for pipe properties and leak source location parameters. Specifically, improving the inversion for solving for pipe properties and beamforming for identifying a leak source location. For inversion and beamforming, the traditional bottleneck of efficiency may be identified in the forward model. An improvement of traditional forward modeling may lie in a Fourier Neural Operator (FNO) or a Physics-Informed Neural Operator (PINO). Herein, FNO or PINO applications may be implemented interchangeably. Additionally, FNO or PINO applications may be defined broadly as a neural operator. A neural operator may be defined as an FNO, PINO, or any other acceptable neural operator. Neural operators, unlike the neural network, may map a function to another function. Traditional complex numerical calculation, such as solving a partial differential equation (PDE), traditionally performed by a forward model may be replaced with a FNO or PINO to implement a neural operator. FNO's and PINO's may be used with downhole measurements in inversion and beamforming to determine pipe properties or a leak source location.

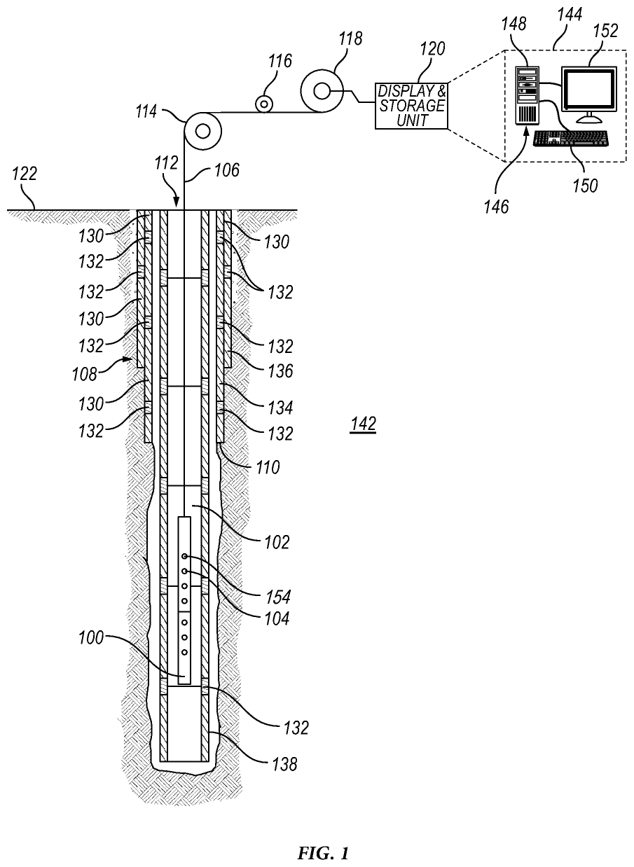

FIG. 1 illustrates an example of an operating environment for a downhole tool 100 as disclosed herein. downhole tool 100 may comprise a transmitter 154 and/or a receiver 104 and is disposed in wellbore 102. In examples, transmitters 154 and receivers 104 may be coil antennas. Furthermore, transmitter 154 and receiver 104 may be separated by a space between about 0.1 inches (0.254 cm) to about 200 inches (508 cm). In examples, downhole tool 100 may be an induction tool that may operate with continuous wave execution of at least one frequency. This may be performed with any number of transmitters 154 and/or any number of receivers 104, which may be disposed on downhole tool 100. In additional examples, transmitter 154 may function and/or operate as a receiver 104. Downhole tool 100 may be operatively coupled to a conveyance 106 (e.g., wireline, slickline, coiled tubing, pipe, downhole tractor, and/or the like) which may provide mechanical suspension, as well as electrical connectivity, for downhole tool 100. Conveyance 106 and downhole tool 100 may extend within casing string 108 to a desired depth within the wellbore 102. Conveyance 106, which may include one or more electrical conductors, may exit wellhead 112, may pass around pulley 114, may engage odometer 116, and may be reeled onto winch 118, which may be employed to raise and lower the tool assembly in the wellbore 102. Signals recorded by downhole tool 100 may be stored on memory and then processed by display and storage unit 120 after recovery of downhole tool 100 from wellbore 102. Alternatively, signals recorded by downhole tool 100 may be conducted to display and storage unit 120 by way of conveyance 106. Display and storage unit 120 may process the signals, and the information contained therein may be displayed for an operator to observe and stored for future processing and reference. It should be noted that an operator may include an individual, group of individuals, or organization, such as a service company. Alternatively, signals may be processed downhole prior to receipt by display and storage unit 120 or both downhole and at surface 122, for example, by display and storage unit 120. Display and storage unit 120 may also contain an apparatus for supplying control signals and power to downhole tool 100. Typical casing string 108 may extend from wellhead 112 at or above ground level to a selected depth within a wellbore 102. Casing string 108 may comprise a plurality of joints 130 or segments of casing string 108, each joint 130 being connected to the adjacent segments by a collar 132. There may be any number of layers in casing string 108.

FIG. 1 also illustrates a typical pipe string 138, which may be positioned inside of casing string 108 extending part of the distance down wellbore 102. Pipe string 138 may be production tubing, tubing string, casing string, or other pipe disposed within casing string 108. Pipe string 138 may comprise concentric pipes. It should be noted that concentric pipes may be connected by collars 132. Downhole tool 100 may be dimensioned so that it may be lowered into the wellbore 110 through pipe string 138, thus avoiding the difficulty and expense associated with pulling pipe string 138 out of wellbore 102.

In logging systems, such as, for example, logging systems utilizing the downhole tool 100, a digital telemetry system may be employed, wherein an electrical circuit may be used to both supply power to downhole tool 100 and to transfer data between display and storage unit 120 and downhole tool 100. A DC voltage may be provided to downhole tool 100 by a power supply located above ground level, and data may be coupled to the DC power conductor by a baseband current pulse system. Alternatively, downhole tool 100 may be powered by batteries located within the downhole tool assembly, and/or the data provided by downhole tool 100 may be stored within the downhole tool assembly, rather than transmitted to the surface during logging (corrosion detection).

Downhole tool 100 may be used for excitation of transmitter 154. Transmitter 154 may broadcast electromagnetic fields into subterranean formation 142. It should be noted that broadcasting EM fields may also be referred to as transmitting EM fields. The EM fields from transmitter 154 may be referred to as a primary EM field. The primary EM fields may produce Eddy currents in casing string 108 and pipe string 138. These Eddy currents, in turn, produce secondary EM fields that may be sensed and/or measured with the primary EM fields by receivers 104. Characterization of casing string 108 and pipe string 138, including determination of pipe attributes, may be performed by measuring and processing these EM fields. Pipe attributes may include, but are not limited to, pipe thickness, pipe conductivity, and/or pipe permeability.

As illustrated, receivers 104 may be positioned on the downhole tool 100 at selected distances (e.g., axial spacing) away from transmitters 154. The axial spacing of receivers 104 from transmitters 154 may vary, for example, from about 0 inches (0 cm) to about 40 inches (101.6 cm) or more. It should be understood that the configuration of downhole tool 100 shown on FIG. 1 is merely illustrative and other configurations of downhole tool 100 may be used with the present techniques. A spacing of 0 inches (0 cm) may be achieved by collocating coils with different diameters. While FIG. 1 shows only a single array of receivers 104, there may be multiple sensor arrays where the distance between transmitter 154 and receivers 104 in each of the sensor arrays may vary. In addition, downhole tool 100 may include more than one transmitter 154 and more or less than six of the receivers 104. In addition, transmitter 154 may be a coil implemented for transmission of magnetic field while also measuring EM fields, in some instances. Where multiple transmitters 154 are used, their operation may be multiplexed or time multiplexed. For example, a single transmitter 154 may broadcast, for example, a multi-frequency signal or a broadband signal. While not shown, downhole tool 100 may include a transmitter 154 and receiver 104 that are in the form of coils or solenoids coaxially positioned within a downhole tubular (e.g., casing string 108) and separated along the tool axis. Alternatively, downhole tool 100 may include a transmitter 154 and receiver 104 that are in the form of coils or solenoids coaxially positioned within a downhole tubular (e.g., casing string 108) and collocated along the tool axis.

Broadcasting of EM fields by the transmitter 154 and the sensing and/or measuring of secondary EM fields by receivers 104 may be controlled by display and storage unit 120, which may include an information handling system 144. As illustrated, the information handling system 144 may be a component of the display and storage unit 120. Alternatively, the information handling system 144 may be a component of downhole tool 100. An information handling system 144 may include any instrumentality or aggregate of instrumentalities operable to compute, estimate, classify, process, transmit, broadcast, receive, retrieve, originate, switch, store, display, manifest, detect, record, reproduce, handle, or utilize any form of information, intelligence, or data for business, scientific, control, or other purposes. For example, an information handling system 144 may be a personal computer, a network storage device, or any other suitable device and may vary in size, shape, performance, functionality, and price.

Information handling system 144 may include a processing unit 146 (e.g., microprocessor, central processing unit, etc.) that may process EM log data by executing software or instructions obtained from a local non-transitory computer readable media 148 (e.g., optical disks, magnetic disks). The non-transitory computer readable media 148 may store software or instructions of the methods described herein. Non-transitory computer readable media 148 may include any instrumentality or aggregation of instrumentalities that may retain data and/or instructions for a period of time. Non-transitory computer readable media 148 may include, for example, storage media such as a direct access storage device (e.g., a hard disk drive or floppy disk drive), a sequential access storage device (e.g., a tape disk drive), compact disk, CD-ROM, DVD, RAM, ROM, electrically erasable programmable read-only memory (EEPROM), and/or flash memory; as well as communications media such wires, optical fibers, microwaves, radio waves, and other EM and/or optical carriers; and/or any combination of the foregoing. Information handling system 144 may also include input device(s) 150 (e.g., keyboard, mouse, touchpad, etc.) and output device(s) 152 (e.g., monitor, printer, etc.). The input device(s) 150 and output device(s) 152 provide a user interface that enables an operator to interact with downhole tool 100 and/or software executed by processing unit 146, For example, information handling system 144 may enable an operator to select analysis options, view collected log data, view analysis results, and/or perform other tasks.

Downhole tool 100 may use any suitable EM technique based on Eddy current (“EC”) for inspection of concentric pipes (e.g., casing string 108 and pipe string 138). EC techniques may be particularly suited for characterization of a multi-string arrangement in which concentric pipes are used. EC techniques may include, but are not limited to, frequency-domain EC techniques and time-domain EC techniques.

In frequency domain EC techniques, transmitter 154 of downhole tool 100 may be fed by a continuous sinusoidal signal, producing primary magnetic fields that illuminate the concentric pipes (e.g., casing string 108 and pipe string 138). The primary EM fields produce Eddy currents in the concentric pipes. These Eddy currents, in turn, produce secondary EM fields that may be sensed and/or measured with the primary EM fields by the receivers 104. Characterization of the concentric pipes may be performed by measuring and processing these EM fields.

In time domain EC techniques, which may also be referred to as pulsed EC (“PEC”), transmitter 154 may be fed by a pulse. Transient primary EM fields may be produced due the transition of the pulse from “off” to “on” state or from “on” to “off” state (more common). These transient EM fields produce EC in the concentric pipes (e.g., casing string 108 and pipe string 138). The EC, in turn, produce secondary EM fields that may be sensed and/or measured by receivers 104 placed at some distance on the downhole tool 100 from transmitter 154, as shown on FIG. 1. Alternatively, the secondary EM fields may be sensed and/or measured by a co-located receiver (not shown) or with transmitter 154 itself.

It should be understood that while casing string 108 is illustrated as a single casing string, there may be multiple layers of concentric pipes disposed in the section of wellbore 102 with casing string 108. EM log data may be obtained in two or more sections of wellbore 102 with multiple layers of concentric pipes. For example, downhole tool 100 may make a first measurement of pipe string 138 comprising any suitable number of joints 130 connected by collars 132. Measurements may be taken in the time-domain and/or frequency range. Downhole tool 100 may make a second measurement in a casing string 108 of first casing 134, wherein first casing 134 comprises any suitable number of pipes connected by collars 132. Measurements may be taken in the time-domain and/or frequency domain. These measurements may be repeated any number of times and for second casing 136 and/or any additional layers of casing string 108. In this disclosure, as discussed further below, methods may be utilized to determine the location of any number of collars 132 in casing string 108 and/or pipe string 138. Determining the location of collars 132 in the frequency domain and/or time domain may allow for accurate processing of recorded data in determining properties of casing string 108 and/or pipe string 138 such as corrosion. As mentioned above, measurements may be taken in the frequency domain and/or the time domain.

In frequency domain EC, the frequency of the excitation may be adjusted so that multiple reflections in the wall of the pipe (e.g., casing string 108 or pipe string 138) are insignificant, and the spacing between transmitters 154 and/or receiver 104 is large enough that the contribution to the mutual impedance from the dominant (but evanescent) waveguide mode is small compared to the contribution to the mutual impedance from the branch cut component. The remote-field eddy current (RFEC) effect may be observed. In a RFEC regime, the mutual impedance between the coil of transmitter 154 and coil of one of the receivers 104 may be sensitive to the thickness of the pipe wall. To be more specific, the phase of the impedance varies as:

$$φ = 2 \sqrt{\frac{ωμσ}{2}} t \qquad ( 1 )$$

and the magnitude of the impedance shows the dependence:

$$exp [ - 2 ( \sqrt{\frac{ωμσ}{2}} ) t ] \qquad ( 2 )$$

where ω is the angular frequency of the excitation source, μ is the magnetic permeability of the pipe, σ is the electrical conductivity of the pipe, and t is the thickness of the pipe. By using the common definition of skin depth for the metals as:

$$δ = \sqrt{\frac{2}{ωμσ}} \qquad ( 3 )$$

The phase of the impedance varies as:

$$φ ≅ 2 \frac{t}{δ} \qquad ( 4 )$$

and the magnitude of the impedance shows the dependence:

$$exp [ \frac{- 2 t}{δ} ] \qquad ( 5 )$$

In RFEC, the estimated quantity may be the overall thickness of the metal. Thus, for multiple concentric pipes, the estimated parameter may be the overall or sum of the thicknesses of the pipes. The quasi-linear variation of the phase of mutual impedance with the overall metal thickness may be employed to perform fast estimation to estimate the overall thickness of multiple concentric pipes. For this purpose, for any given set of pipes dimensions, material properties, and tool configuration, such linear variation may be constructed quickly and may be used to estimate the overall thickness of concentric pipes. Information handling system 144 may enable an operator to select analysis options, view collected log data, view analysis results, and/or perform other tasks.

Monitoring the condition of pipe string 138 and casing string 108 may be performed on information handling system 144 in oil and gas field operations. Information handling system 144 may be utilized with EM (EM) Eddy Current (EC) techniques to inspect pipe string 138 and casing string 108. EM EC techniques may include frequency-domain EC techniques and time-domain EC techniques. In time-domain and frequency-domain techniques, one or more transmitters 154 may be excited with an excitation signal which broadcast an EM field and receiver 104 may sense and/or measure the reflected excitation signal, a secondary EM field, for interpretation. The received signal is proportional to the amount of metal that is around transmitter 154 and receiver 104. For example, less signal magnitude is typically an indication of more metal, and more signal magnitude is an indication of less metal. This relationship may be utilized to determine metal loss, which may be due to an abnormality related to the pipe such as corrosion or buckling.

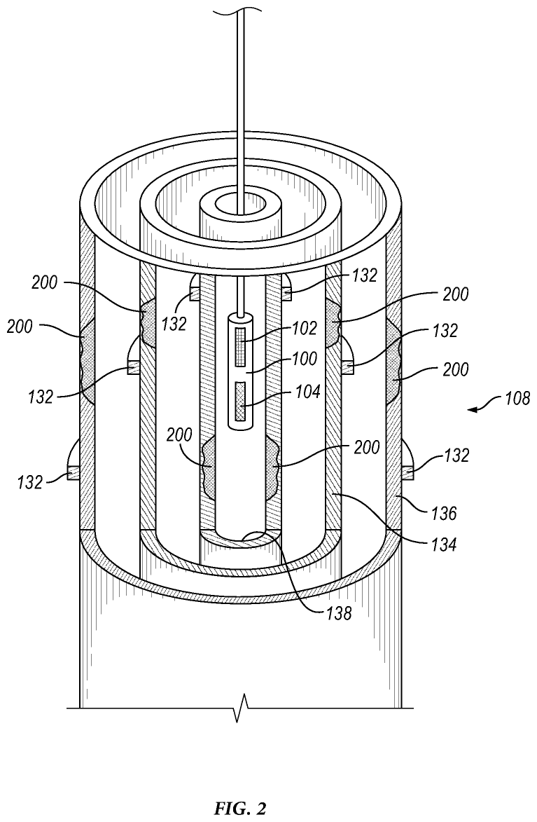

FIG. 2 illustrates downhole tool 100 disposed in pipe string 138 which may be surrounded by a plurality of nested pipes (e.g., first casing 134 and second casing 136) and an illustration of anomalies 200 disposed within the plurality of nested pipes, in accordance with some embodiments. As downhole tool 100 moves across pipe string 138 and casing string 108, one or more transmitters 154 may be excited, and a signal (mutual impedance between 102 transmitter and receiver 104) at one or more receivers 104, may be recorded.

Due to eddy current physics and EM attenuation, pipe string 138 and/or casing string 108 may generate an electrical signal that is in the opposite polarity to the incident signal and results in a reduction in the received signal. Typically, more metal volume translates to more lost signal. As a result, by inspecting the signal gains, it is possible to identify zones with metal loss (such as corrosion). In order to distinguish signals that originate from anomalies at different pipes of a multiple nested pipe configuration, multiple transmitter-receiver spacing, and frequencies may be utilized. For example, short spaced transmitters 154 and receivers 104 may be sensitive to first casing 134, while longer spaced transmitters 154 and receivers 104 may be sensitive to second casing 136 and/or deeper (3rd, 4th, etc.) pipes. By analyzing the signal levels at these different channels with inversion methods, it is possible to relate a certain received signal to a certain metal loss or gain at each pipe. In addition to loss of metal, other pipe properties such as magnetic permeability and conductivity may also be estimated by inversion methods. It should be noted that inversion methods may include model-based inversion which may include forward modeling.

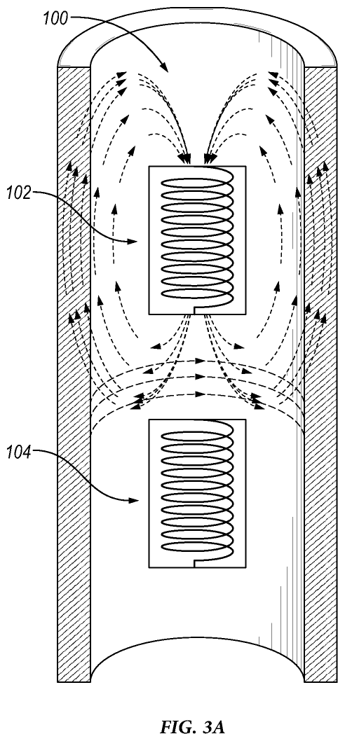

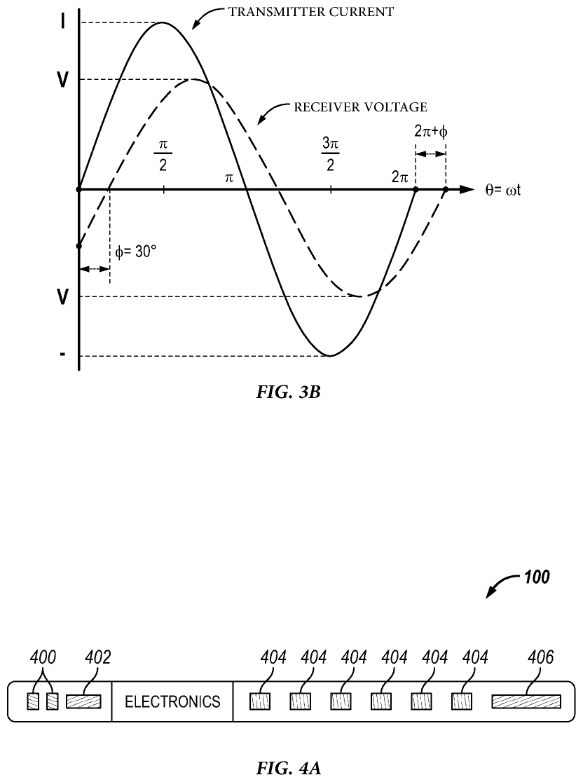

FIG. 3A illustrates an operation of downhole tool 100. In examples, downhole tool 100 may function by exciting transmitter 154 with a continuous sinusoidal current. In effect, transmitter 154 may transmit a magnetic field or primary EM waves. Subsequently, as the primary waves travel away from transmitter 154, the primary waves may induce an eddy current in casing string 108 and/or pipe string 138. Herein, casing string 108 and/or pipe string 138 may be defined as one or more tubulars. Eddy currents may then be produced along the one or more tubulars. Eddy currents inherently produce secondary EM waves. The primary and secondary EM waves may then produce a voltage across receiver 104.

FIG. 3B illustrates a graph of transmitter current and receiver voltage across a range of phases. For FIG. 3B phase is the dependent axis and the independent axis is shared between transmitter current and receiver voltage. As illustrated the amplitude of the transmitter current may be identified as I and the amplitude of the receiver voltage V. The phase shift between transmitter current and receiver voltage may be 30 degrees.

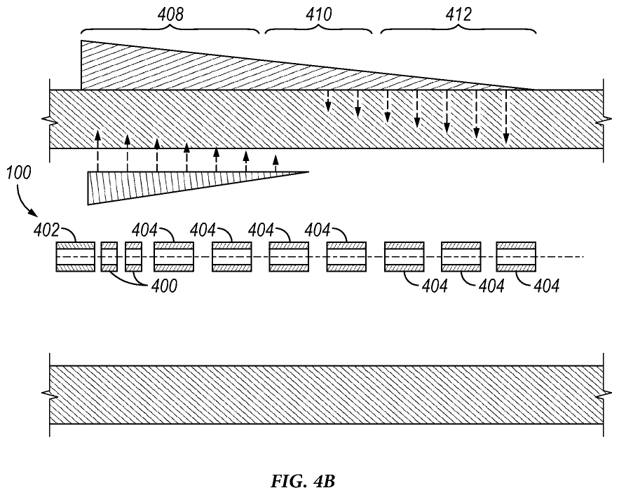

FIG. 4A illustrates one or more high resolution receivers 400, high resolution transmitter 402, low resolution receivers 404, and low-resolution transmitter 406. As illustrated, there are two high resolution receivers 400 and six low resolution receivers 404 disposed on downhole tool 100. However, any number of high-resolution receivers 400 and low-resolution receivers 404 may be disposed on downhole tool 100. Likewise, there is a low resolution transmitter 402 and high resolution transmitter 406 disposed on downhole tool 100. However, there may be any number of transmitters disposed on downhole tool 100. High resolution transmitters 402 and low resolution transmitters 406 may each emit a continuous electromagnet (EM) wave between 0.1 and 1,000 Hz. High resolution receivers 400 may be tuned to receive higher frequencies between 10 and 1,000 Hz, such frequencies may be emitted from tubulars closer to downhole tool 100. Herein, frequencies between 0.1 and 1,000 are near field. In comparison, low resolution receivers 404 may be tuned for lower frequencies between 0.1 and 100 Hz, such frequencies may be emitted from tubulars all tubulars. Herein, frequencies between 0.1 and 1000 Hz are far field. There may also exist a crossover or space of the near and far fields between 0.1 and 1000 Hz herein the transition zone.

Each receiver from high-resolution receivers 400 and low-resolution receivers 404 may be configured to record complex-valued measurements (amplitude and phase). Further, traditional operations may only measure the far field. Therefore, taking the far field and comparing it to the near field, individual pipe thickness may be extrapolated. FIG. 4B illustrates near field 408, transition zone 410, and far field 412 compared to each receiver disposed on downhole tool 100. As previously described, far field 412 may be induced by low resolution transmitter 406 and observed along all tubulars of a pipe plan and measured by at least low resolution receivers 404. Near field 408 may be induced by high resolution transmitter 402 observed along pipes near downhole tool 100 and measured by at least high resolution receivers 400. However, transition zone 410 may be induced by either both or one of each of the low resolution transmitter 406 and high resolution transmitter 402 and measured by both or one of each of the low resolution receivers 400 and high resolution receivers 404. Using EM measurements from near field 408, transition zone 410, and far field 412 at least one metal pipe thickness may be obtained with a traditional inversion. EM measurements from near field 408, transition zone 410, and far field 412 may include at least resistivity, permittivity, or permeability. The systems and methods described below may enhance or replace the inversion to determine at least one metal pipe thickness with measurements from near field 408, transition zone 410, and far field 412.

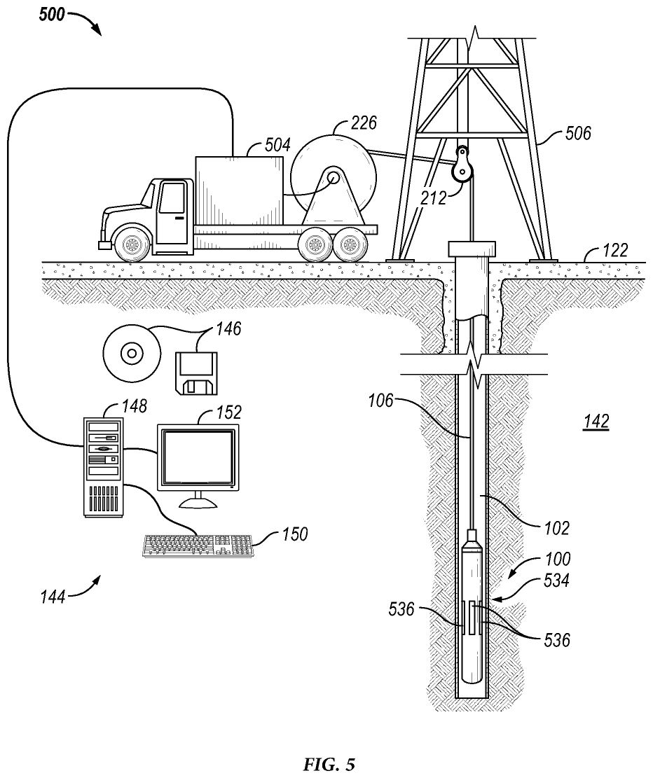

In examples, downhole tool 100 may not only be applied to EM implementations for tubular inspection. For example, FIG. 5 illustrates an example of an operating environment for a downhole tool 100 with acoustic leak source implementations, well measurement system 500. As illustrated, well measurement system 500 may comprise downhole tool 100 attached to vehicle 504. In examples, it should be noted that downhole tool 100 may not be attached to a vehicle 504. Downhole tool 100 may be supported by rig 506 at surface 122. Downhole tool 100 may be tethered to vehicle 504 through conveyance 106. Conveyance 106 may be disposed around one or more sheave wheels 212 to vehicle 504. Conveyance 106 may include any suitable means for providing mechanical conveyance for downhole tool 100, including, but not limited to, wireline, slickline, coiled tubing, pipe, drill pipe, downhole tractor, or the like. In some embodiments, conveyance 106 may provide mechanical suspension, as well as electrical and/or optical connectivity, for downhole tool 100. Conveyance 106 may comprise, in some instances, a plurality of electrical conductors and/or a plurality of optical conductors extending from vehicle 504, which may provide power and telemetry. In examples, an optical conductor may utilize a battery and/or a photo conductor to harvest optical power transmitted from surface 122. Conveyance 106 may comprise an inner core of seven electrical conductors covered by an insulating wrap. An inner and outer steel armor sheath may be wrapped in a helix in opposite directions around the conductors. The electrical and/or optical conductors may be used for communicating power and telemetry between vehicle 504 and downhole tool 100. Information from downhole tool 100 may be gathered and/or processed by information handling system 144. For example, signals recorded by receiver 104 may be stored on memory and then processed by downhole tool 100.

The processing may be performed real-time during data acquisition or after recovery of downhole tool 100. Processing may alternatively occur downhole or may occur both downhole and at surface. In some embodiments, signals recorded by downhole tool 100 may be conducted to information handling system 144 by way of conveyance 106. Information handling system 144 may process the signals, and the information contained therein may be displayed for an operator to observe and stored for future processing and reference. Information handling system 144 may also contain an apparatus for supplying control signals and power to downhole tool 100.

Systems and methods of the present disclosure may be implemented, at least in part, with Information handling system 144. While shown at surface 122, information handling system 144 may also be located at another location, such as remote from wellbore 102. Information handling system 144 may include any instrumentality or aggregate of instrumentalities operable to compute, estimate, classify, process, transmit, receive, retrieve, originate, switch, store, display, manifest, detect, record, reproduce, handle, or utilize any form of information, intelligence, or data for business, scientific, control, or other purposes. For example, an information handling system 144 may be a personal computer, a network storage device, or any other suitable device and may vary in size, shape, performance, functionality, and price. Information handling system 144 may include random access memory (RAM), one or more processing resources such as a central processing unit (CPU) or hardware or software control logic, ROM, and/or other types of nonvolatile memory. Additional components of the information handling system 144 may include one or more disk drives, one or more network ports for communication with external devices as well as various input and output (I/O) devices, such as an input device(s) 150, a mouse, and an output device(s) 152. Information handling system 144 may also include one or more buses operable to transmit communications between the various hardware components. Furthermore, output device(s) 152 may provide an image to a user based on activities performed by personal computer.

For example, producing images of geological structures created from recorded signals. By way of example, video display unit may produce a plot of depth versus the two cross-axial components of the gravitational field and versus the axial component in wellbore 102 coordinates. The same plot may be produced in coordinates fixed to the Earth, such as coordinates directed to the North, East and directly downhole (Vertical) from the point of entry to the wellbore. A plot of overall (average) density versus depth in wellbore or vertical coordinates may also be provided. A plot of density versus distance and direction from the wellbore 102 versus vertical depth may be provided. It should be understood that many other types of plots are possible when the actual position of the measurement point in North, East and Vertical coordinates is taken into account. Additionally, hard copies of the plots may be produced in paper logs for further use.

Alternatively, systems and methods of the present disclosure may be implemented, at least in part, with non-transitory computer-readable media 148. Non-transitory computer-readable media 148 may include any instrumentality or aggregation of instrumentalities that may retain data and/or instructions for a period of time. Non-transitory computer-readable media 148 may include, for example, storage media such as a direct access storage device (e.g., a hard disk drive or floppy disk drive), a sequential access storage device (e.g., a tape disk drive), compact disk, CD-ROM, DVD, RAM, ROM, electrically erasable programmable read-only memory (EEPROM), and/or flash memory; as well as communications media such wires, optical fibers, microwaves, radio waves, and other EM and/or optical carriers; and/or any combination of the foregoing.

In examples, rig 506 includes a load cell (not shown) which may determine the amount of pull on conveyance 106 at the surface of wellbore 102. Information handling system 144 may comprise a safety valve (not illustrated) which controls the hydraulic pressure that drives drum 526 on vehicle 504 which may reel up and/or release conveyance 106 which may move downhole tool 100 up and/or down wellbore 102. The safety valve may be adjusted to a pressure such that drum 526 may only impart a small amount of tension to conveyance 106 over and above the tension necessary to retrieve conveyance 106 and/or downhole tool 100 from wellbore 102. The safety valve is typically set a few hundred pounds above the amount of desired safe pull on conveyance 106 such that once that limit is exceeded, further pull on conveyance 106 may be prevented.

As illustrated in FIG. 5, downhole tool 100 may include measurement assembly 534. It should be noted that measurement assembly 534 may make up at least a part of downhole tool 100. Without limitation, any number of different measurement assemblies, communication assemblies, battery assemblies, and/or the like may form downhole tool 100 with measurement assembly 534. Additionally, measurement assembly 534 may form downhole tool 100 itself. In examples, measurement assembly 534 may comprise at least one transducer 536, which may be disposed at the surface of measurement assembly 534. Without limitation, transducer 536 may also be disposed within measurement assembly 534. Without limitation, there may be four transducers 536 that may be disposed ninety degrees from each other. However, it should be noted that there may be any number of transducers 536 disposed along downhole tool 100 at any degree from each other. Transducers 236 may function and operate to generate an acoustic pressure pulse in the wellbore fluid. In examples, measurement assembly 534 may also comprise at least transducer 536, which may be disposed at the surface of measurement assembly 534 and/or transducer 536 may also be disposed within measurement assembly 534. Without limitation, there may be four transducers 536 that may be disposed ninety degrees from each other. Additionally, transducers 536 may be aligned on top of each other and spaced about the axis of downhole tool 100. Transducers 536 may function and operate to receive an acoustic pressure pulse which may be referred to as an acoustic wave that travels through wellbore fluids.

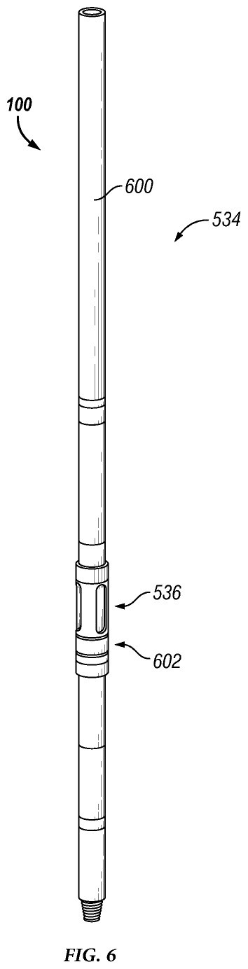

FIG. 6 illustrates an expanded view of measurement assembly 534. As illustrated, measurement assembly 534 may comprise at least one battery section 600 and at least on instrument section 602. Battery section 600 may operate and function to enclose and/or protect at least one battery that may be disposed in battery section 600. Without limitation, battery section 300 may also operate and function to power measurement assembly 534. Specifically, battery section 600 may power at least one transducer, which may be disposed at any end of battery section 600 in instrument section 602.

Instrument section 602 may house at least one transducer 536. As describe above, transducer 536 may operate and function and operate to generate a pressure pulse that travels through wellbore fluids. The pressure pulse may have a frequency range from 10 Hz˜20 kHz. It should be noted that the pulse signal may be emitted with different frequency content. In examples, transducers 536 may be referred to as a transmitter, which generates a pressure pulse, travelling in the wellbore fluids to interact with wellbore 102 (e.g., referring to FIG. 1). In examples, a pressure pulse may be referred to as an acoustic wave and/or acoustic waves, as seen below. During operations a pressure pulse may reflect of any number of surfaces in wellbore 102. The reflected acoustic waves may be received by at least one transducer 536.

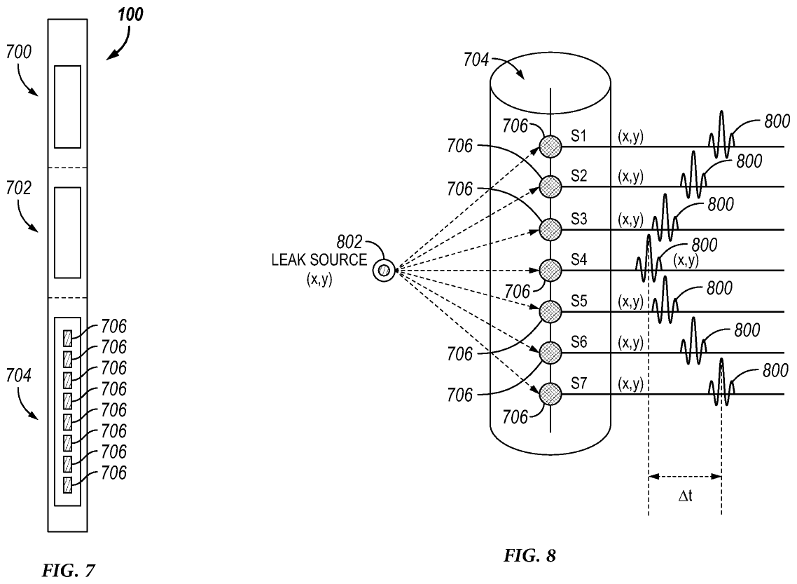

FIG. 7 illustrates another example of how downhole tool 100 may function and operate. In examples, downhole tool 100 may have a diameter of 1 to 16 inches (2.54-40.64 cm), it may run along a conveyance. Additionally, telemetry section 700, detection receiver electronics (DRE) section 702, and detection receiver array (DRA) 704 may each have a longitudinal length between 50 and 100 inches (127-254 cm). Further, downhole tool 100 may weigh between 20 and 100 pounds (9.07-45.4 kg) However, any range provided may be extended to what is standard in the art. Telemetry section 700 may be configured to communicate with information handling system 144 (e.g., referring to FIG. 1) via standard techniques known in the art. DRE section 702 may perform adjustable sampling, include a processor for advanced signal sampling, and a power supply. DRA section 704 may include any number of broadband sensitive hydrophones 706. Broadband sensitive hydrophones 706 may each be individually selected for a specific frequency range, or any number may be aligned to receive any range of acoustic waves. Additionally, DRA section 704 may comprise gains to support a wide range of acoustic waves.

Acoustic waves emitted from downhole tool 100 and traveling through wellbore 102 may be received and processed, as described in FIG. 7. As acoustic waves travel through wellbore 102, they may encounter a leak source. Herein, a leak source may be defined as a location where there is a leak in one or more tubulars such that the leak allows for the flow of fluid through the tubular. FIG. 8 illustrates such a leak source 802 and how DRA section 704 with seven hydrophones 706 may measure the difference in acoustic event timing or phase shift of the wave forms. Unlike electromagnetic (EM) implementations discussed above, which may use multiple discrete frequencies source to detect corrosion in pipes, on acoustic source is a continuous wavelet in time-domain which contains many frequencies. A reflected acoustic wave 800 may be measured with hydrophones 706 as a function of time. Reflected time-variant vibration redundancy may be utilized to determine the 2D leak source location information. Herein x and y may be represented as horizontal and vertical distances in wellbore 102. Traditionally an algorithm may invert the measurement to get the material function by employing the numerical solution of the wave equation. This is time-consuming since solving partial differential equations (PDE) equation is cumbersome. With the development of AI, information handling system 144 (e.g., referring to FIG. 1) may run artificial intelligence (AI) algorithms and neural operators. This may allow an information handling system 144 to run on reflected acoustic wave 800 to be mapped to leak source 802.

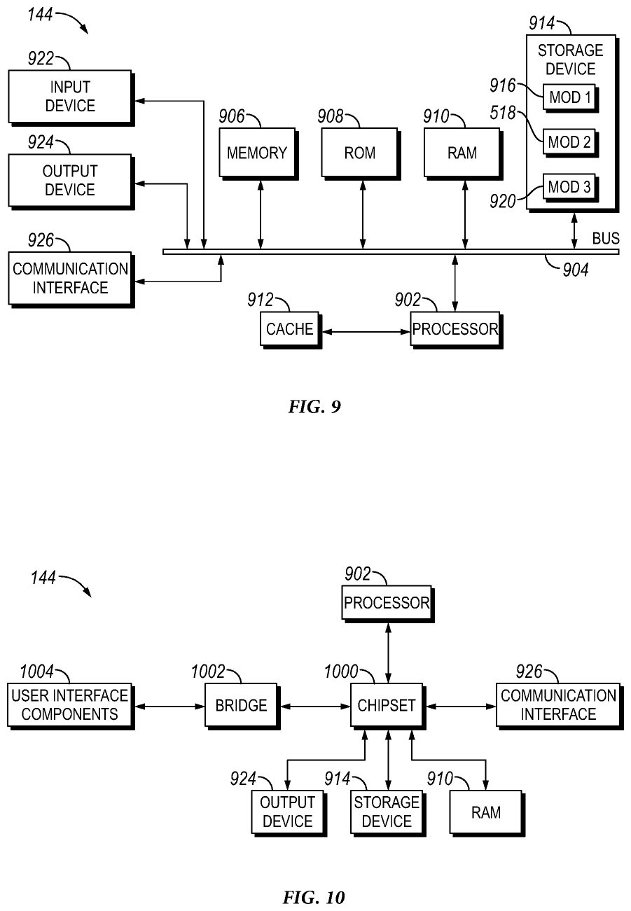

FIG. 9 illustrates information handling system 144 which may be employed to perform various blocks, methods, and techniques disclosed herein. As illustrated, information handling system 144 includes a processing unit (CPU or processor) 902 and a system bus 904 that couples various system components including system memory 906 such as read only memory (ROM) 908 and random-access memory (RAM) 910 to processor 902. Processors disclosed herein may all be forms of this processor 902. Information handling system 144 may include a cache 912 of high-speed memory connected directly with, in close proximity to, or integrated as part of processor 902. Information handling system 144 copies data from memory 906 and/or storage device 214 to cache 912 for quick access by processor 902. In this way, cache 912 provides a performance boost that avoids processor 902 delays while waiting for data. These and other modules may control or be configured to control processor 902 to perform various operations or actions. Other system memory 906 may be available for use as well. Memory 906 may include multiple different types of memory with different performance characteristics. It may be appreciated that the disclosure may operate on information handling system 144 with more than one processor 902 or on a group or cluster of computing devices networked together to provide greater processing capability. Processor 902 may include any general-purpose processor and a hardware module or software module, such as first module 916, second module 918, and third module 920 stored in storage device 914, configured to control processor 902 as well as a special-purpose processor where software instructions are incorporated into processor 902. Processor 902 may be a self-contained computing system, containing multiple cores or processors, a bus, memory controller, cache, etc. A multi-core processor may be symmetric or asymmetric. Processor 902 may include multiple processors, such as a system having multiple, physically separate processors in different sockets, or a system having multiple processor cores on a single physical chip. Similarly, processor 902 may include multiple distributed processors located in multiple separate computing devices but working together such as via a communications network. Multiple processors or processor cores may share resources such as memory 906 or cache 912 or may operate using independent resources. Processor 902 may include one or more state machines, an application specific integrated circuit (ASIC), or a programmable gate array (PGA) including a field PGA (FPGA).

Each individual component discussed above may be coupled to system bus 904, which may connect each and every individual component to each other. System bus 904 may be any of several types of bus structures including a memory bus or memory controller, a peripheral bus, and a local bus using any of a variety of bus architectures. A basic input/output (BIOS) stored in ROM 908 or the like, may provide the basic routine that helps to transfer information between elements within information handling system 144, such as during start-up. Information handling system 144 further includes storage devices 914 or computer-readable storage media such as a hard disk drive, a magnetic disk drive, an optical disk drive, tape drive, solid-state drive, RAM drive, removable storage devices, a redundant array of inexpensive disks (RAID), hybrid storage device, or the like. Storage device 914 may include software modules 916, 918, and 920 for controlling processor 902. Information handling system 144 may include other hardware or software modules. Storage device 914 is connected to the system bus 904 by a drive interface. The drives and the associated computer-readable storage devices provide nonvolatile storage of computer-readable instructions, data structures, program modules and other data for information handling system 144. In one aspect, a hardware module that performs a particular function includes the software component stored in a tangible computer-readable storage device in connection with the necessary hardware components, such as processor 902, system bus 904, and so forth, to carry out a particular function. In another aspect, the system may use a processor and computer-readable storage device to store instructions which, when executed by the processor, cause the processor to perform operations, a method or other specific actions. The basic components and appropriate variations may be modified depending on the type of device, such as whether information handling system 144 is a small, handheld computing device, a desktop computer, or a computer server. When processor 902 executes instructions to perform “operations”, processor 902 may perform the operations directly and/or facilitate, direct, or cooperate with another device or component to perform the operations.

As illustrated, information handling system 144 employs storage device 914, which may be a hard disk or other types of computer-readable storage devices which may store data that are accessible by a computer, such as magnetic cassettes, flash memory cards, digital versatile disks (DVDs), cartridges, random access memories (RAMs) 910, read only memory (ROM) 908, a cable containing a bit stream and the like, may also be used in the exemplary operating environment. Tangible computer-readable storage media, computer-readable storage devices, or computer-readable memory devices, expressly exclude media such as transitory waves, energy, carrier signals, EM waves, and signals per se.

To enable user interaction with information handling system 144, an input device 922 represents any number of input mechanisms, such as a microphone for speech, a touch-sensitive screen for gesture or graphical input, keyboard, mouse, motion input, speech and so forth. Additionally, input device 922 may receive acoustic or EM measurements from downhole tool 100, discussed above. An output device 924 may also be one or more of a number of output mechanisms known to those of skill in the art. In some instances, multimodal systems enable a user to provide multiple types of input to communicate with information handling system 144. Communications interface 926 generally governs and manages the user input and system output. There is no restriction on operating on any particular hardware arrangement and therefore the basic hardware depicted may easily be substituted for improved hardware or firmware arrangements as they are developed.

With continued reference to FIG. 4, each individual component describe above is depicted and disclosed as individual functional blocks. The functions these blocks represent may be provided through the use of either shared or dedicated hardware, including, but not limited to, hardware capable of executing software and hardware, such as a processor 902, that is purpose-built to operate as an equivalent to software executing on a general purpose processor. For example, the functions of one or more processors presented in FIG. 9 may be provided by a single shared processor or multiple processors. (Use of the term “processor” should not be construed to refer exclusively to hardware capable of executing software.) Illustrative embodiments may include microprocessor and/or digital signal processor (DSP) hardware, read-only memory (ROM) 908 for storing software performing the operations described below, and random-access memory (RAM) 910 for storing results. Very large-scale integration (VLSI) hardware embodiments, as well as custom VLSI circuitry in combination with a general-purpose DSP circuit, may also be provided.

FIG. 10 illustrates a chipset architecture utilized in the information handling system 144 that may be used in executing the described method and generating and displaying a graphical user interface (GUI). Information handling system 144 is an example of computer hardware, software, and firmware that may be used to implement the disclosed technology. Information handling system 144 may include a processor 902, representative of any number of physically and/or logically distinct resources capable of executing software, firmware, and hardware configured to perform identified computations. Processor 902 may communicate with a chipset 1000 that may control input to and output from processor 902. In this example, chipset 1000 outputs information to output device 924, such as a display, and may read and write information to storage device 914, which may include, for example, magnetic media, and solid-state media. Chipset 1000 may also read data from and write data to RAM 910. A bridge 1002 for interfacing with a variety of user interface components 1004 may be provided for interfacing with chipset 1000. Such user interface components 1004 may include a keyboard, a microphone, touch detection and processing circuitry, a pointing device, such as a mouse, and so on. In general, inputs to information handling system 144 may come from any of a variety of sources, machine generated and/or human generated.

Chipset 1000 may also interface with one or more communication interfaces 926 that may have different physical interfaces. Such communication interfaces may include interfaces for wired and wireless local area networks, for broadband wireless networks, as well as personal area networks. Some applications of the methods for generating, displaying, and using the GUI disclosed herein may include receiving ordered datasets over the physical interface or be generated by the machine itself by processor 902 analyzing data stored in storage device 914 or RAM 910. Further, information handling system 144 receive inputs from a user via user interface components 1004 and execute appropriate functions, such as browsing functions by interpreting these inputs using processor 902.

In examples, information handling system 144 may also include tangible and/or non-transitory computer-readable storage devices for carrying or having computer-executable instructions or data structures stored thereon. Such tangible computer-readable storage devices may be any available device that may be accessed by a general purpose or special purpose computer, including the functional design of any special purpose processor as described above. By way of example, and not limitation, such tangible computer-readable devices may include RAM, ROM, EEPROM, CD-ROM or other optical disk storage, magnetic disk storage or other magnetic storage devices, or any other device which may be used to carry or store desired program code in the form of computer-executable instructions, data structures, or processor chip design. When information or instructions are provided via a network, or another communications connection (either hardwired, wireless, or combination thereof), to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special purpose computer, or special purpose processing device to perform a certain function or group of functions. Computer-executable instructions also include program modules that are executed by computers in stand-alone or network environments. Generally, program modules include routines, programs, components, data structures, objects, and the functions inherent in the design of special-purpose processors, etc. that perform particular tasks or implement particular abstract data types. Computer-executable instructions, associated data structures, and program modules represent examples of the program code means for executing blocks of the methods disclosed herein. The particular sequence of such executable instructions or associated data structures represents examples of corresponding acts for implementing the functions described in such blocks.

In additional examples, methods may be practiced in network computing environments with many types of computer system configurations, including personal computers, hand-held devices, multi-processor systems, microprocessor-based or programmable consumer electronics, network PCs, minicomputers, mainframe computers, and the like. Examples may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

FIG. 11 illustrates an example of one arrangement of resources in a computing network 1100 that may employ the processes and techniques described herein, although many others are of course possible. As noted above, an information handling system 144, as part of their function, may utilize data, which includes files, directories, metadata (e.g., access control list (ACLS) creation/edit dates associated with the data, etc.), and other data objects. The data on the information handling system 144 is typically a primary copy (e.g., a production copy). During a copy, backup, archive or other storage operation, information handling system 144 may send a copy of some data objects (or some components thereof) to a secondary storage computing device 1104 by utilizing one or more data agents 1102.

A data agent 1102 may be a desktop application, website application, or any software-based application that is run on information handling system 144. As illustrated, information handling system 144 may be disposed at any rig site (e.g., referring to FIG. 1), off site location, core laboratory, repair and manufacturing center, and/or the like. In examples, data agent 1102 may communicate with a secondary storage computing device 1104 using communication protocol 1108 in a wired or wireless system. Communication protocol 1108 may function and operate as an input to a website application. In the website application, field data related to pre- and post-operations, generated diagnosed trouble codes (DTCs), notes, and the like may be uploaded. Additionally, information handling system 144 may utilize communication protocol 1108 to access processed measurements, operations with similar DTCs, troubleshooting findings, historical run data, and/or the like. This information is accessed from secondary storage computing device 1104 by data agent 1102, which is loaded on information handling system 144.

Secondary storage computing device 1104 may operate and function to create secondary copies of primary data objects (or some components thereof) in various cloud storage sites 1106A-N. Additionally, secondary storage computing device 1104 may run determinative algorithms on data uploaded from one or more information handling systems 144, discussed further below. Communications between the secondary storage computing devices 1104 and cloud storage sites 1106A-N may utilize REST protocols (Representational state transfer interfaces) that satisfy basic C/R/U/D semantics (Create/Read/Update/Delete semantics), or other hypertext transfer protocol (“HTTP”)-based or file-transfer protocol (“FTP”)-based protocols (e.g., Simple Object Access Protocol).

In conjunction with creating secondary copies in cloud storage sites 1106A-N, the secondary storage computing device 1104 may also perform local content indexing and/or local object-level, sub-object-level or block-level deduplication when performing storage operations involving various cloud storage sites 1106A-N. Cloud storage sites 1106A-N may further record and maintain, EM logs, map DTC codes, store repair and maintenance data, store operational data, and/or provide outputs from determinative algorithms that are located in cloud storage sites 1106A-N. In a non-limiting example, this type of network may be utilized as a platform to store, backup, analyze, import, preform extract, transform and load (“ETL”) processes, mathematically process, apply machine learning models, and augment EM measurement data sets.

FIG. 12 illustrates a machine learning model 1200 which may be an empirically derived model which may result from a machine learning algorithm identifying one or more underlying relationships within a dataset. In comparison to a physics-based model, such as Maxwell's Equations, which are derived from first principals and define the mathematical relationship of a system, a pure machine learning model may not be derived from first principals. Once a machine learning model is developed, it may be queried in order to predict one or more outcomes for a given set of inputs. The type of input data used to query the model to create the prediction may correlate both in category and type to the dataset from which the model was developed.

The structure of, and the data contained within a dataset provided to a machine learning algorithm may vary depending on the intended function of the resulting machine learning model. The rows of data, or data points, within a dataset may contain one or more independent values. Additionally, datasets may contain corresponding dependent values. The independent values of a dataset may be referred to as “features,” and a collection of features may be referred to as a “feature space.” If dependent values are available in a dataset, they may be referred to as outcomes or “target values.” Although dependent values may be a necessary component of a dataset for certain algorithms, not all algorithms require a dataset with dependent values. Furthermore, both the independent and dependent values of the dataset may comprise either numerical or categorical values.

While it may be true that machine learning model development is more successful with a larger dataset, it may also be the case that the whole dataset isn't used to train the model. A test dataset may be a portion of the original dataset which is not presented to the algorithm for model training purposes. Instead, the test dataset may be used for what may be known as “model validation,” which may be a mathematical evaluation of how successfully a machine learning algorithm has learned and incorporated the underlying relationships within the original dataset into a machine learning model. This may include evaluating model performance according to whether the model is over-fit or under-fit. As it may be assumed that all datasets contain some level of error, it may be important to evaluate and optimize the model performance and associated model fit by means of model validation. In general, the variability in model fit (e.i. whether a model is over-fit or under-fit) may be described by the “bias-variance trade-off” As an example, a model with high bias may be an under-fit model, where the developed model is over-simplified, and has either not fully learned the relationships within the dataset or has over-generalized the underlying relationships. A model with high variance may be an over-fit model which has overlearned about non-generalizable relationships within training dataset which may not be present in the test dataset. In a non-limiting example, these non-generalizable relationships may be driven by factors such as intrinsic error, data heterogeneity, and the presence of outliers within the dataset. The selected ratio of training data to test data may vary based on multiple factors, including, in a non-limiting example, the homogeneity of the dataset, the size of the dataset, the type of algorithm used, and the objective of the model. The ratio of training data to test data may also be determined by the validation method used, wherein some non-limiting examples of validation methods include k-fold cross-validation, stratified k-fold cross-validation, bootstrapping, leave-one-out cross-validation, resubstituting, random subsampling, and percentage hold-out.

In addition to the parameters that exist within the dataset, such as the independent and dependent variables, machine learning algorithms may also utilize parameters referred to as “hyperparameters.” Each algorithm may have an intrinsic set of hyperparameters which guide what and how an algorithm learns about the training dataset by providing limitations or operational boundaries to the underlying mathematical workflows on which the algorithm functions. Furthermore, hyperparameters may be classified as either model hyperparameters or algorithm parameters.

Model hyperparameters may guide the level of nuance with which an algorithm learns about a training dataset, and as such model hyperparameters may also impact the performance or accuracy of the model that is ultimately generated. Modifying or tuning the model hyperparameters of an algorithm may result in the generation of substantially different models for a given training dataset. In some cases, the model hyperparameters selected for the algorithm may result in the development of an over-fit or under-fit model. As such, the level to which an algorithm may learn the underlying relationships within a dataset, including the intrinsic error, may be controlled to an extent by tuning the model hyperparameters.

Model hyperparameter selection may be optimized by identifying a set of hyperparameters which minimize a predefined loss function. An example of a loss function for a supervised regression algorithm may include the model error, wherein the optimal set of hyperparameters correlates to a model which produces the lowest difference between the predictions developed by the produced model and the dependent values in the dataset. In addition to model hyperparameters, algorithm hyperparameters may also control the learning process of an algorithm, however algorithm hyperparameters may not influence the model performance. Algorithm hyperparameters may be used to control the speed and quality of the machine learning process. As such, algorithm hyperparameters may affect the computational intensity associated with developing a model from a specific dataset.

Machine learning algorithms, which may be capable of capturing the underlying relationships within a dataset, may be broken into different categories. One such category may include whether the machine learning algorithm functions using supervised, unsupervised, semi-supervised, or reinforcement learning. The objective of a supervised learning algorithm may be to determine one or more dependent variables based on their relationship to one or more independent variables. Supervised learning algorithms are named as such because the dataset includes both independent and corresponding dependent values where the dependent value may be thought of as “the answer,” that the model is seeking to predict from the underlying relationships in the dataset. As such, the objective of a model developed from a supervised learning algorithm may be to predict the outcome of one or more scenarios which do not yet have a known outcome. Supervised learning algorithms may be further divided according to their function as classification and regression algorithms. When the dependent variable is a label or a categorical value, the algorithm may be referred to as a classification algorithm. When the dependent variable is a continuous numerical value, the algorithm may be a regression algorithm. In a non-limiting example, algorithms utilized for supervised learning may include Neural Networks, K-Nearest Neighbors, Naïve Bayes, Decision Trees, Classification Trees, Regression Trees, Random Forests, Linear Regression, Support Vector Machines (SVM), Gradient Boosting Regression, and Perception Back-Propagation.

The objective of unsupervised machine learning may be to identify similarities and/or differences between the data points within the dataset which may allow the dataset to be divided into groups or clusters without the benefit of knowing which group or cluster the data may belong to. Datasets utilized in unsupervised learning may not include a dependent variable as the intended function of this type of algorithm is to identify one or more groupings or clusters within a dataset. In a non-limiting example, algorithms which may be utilized for unsupervised machine learning may include K-means clustering, K-means classification, Fuzzy C-Means, Gaussian Mixture, Hidden Markov Model, Neural Networks, and Hierarchical algorithms.

In examples to determine a relationship using machine learning, machine learning model 1200 may be a neural network (NN), as illustrated in FIG. 12, may be utilized for EM tubular monitoring and leak source detection. A NN is an artificial neural network with one or more hidden layers 1202 between input layer 1204 and output layer 1206. As illustrated, input layer 1204 may include all extracted measurements from near field 408, transition field 410, and far field 412 (e.g., referring to FIG. 4B) or from reflected acoustic wave 800 (e.g., referring to FIG. 8) and output layers 1206 may include pipe information from other sources. During operations, input data is taken by neurons 1212 in first layer which then provide an output to the neurons 1212 within next layer and so on which provides a final output in output layer 1206. Each layer may have one or more neurons 1212. The connection between two neurons 1212 of successive layers may have an associated weight. The weight defines the influence of the input to the output for the next neuron 1212 and eventually for the overall final output.

Traditionally, to use a neural operator the input measurement sets may be along the same axis. However, with EM applications, the material function a(r) and physical response u(z) are EM measurements from near field 408, transition zone 410, and far field 412 (e.g., referring to FIG. 4B) along different directions. Herein, material function a(r) is along the radius direction, while physical response u(z) is along the depth direction. Therefore, for EM applications, to apply neural operators, material function a(r) and physical response u(z) may be aligned along the same x axis.

In acoustic applications, leak sources are defined in a 2D domain (z,r). However, measurements are obtained as reflected acoustic wave 800 (e.g., referring to FIG. 8) in another 2D domain, (z,t). Herein z may be defined as depth, r may be defined as radius, and t may be defined as time. For acoustic applications, reflected acoustic wave 800 may be aligned in the 2D domain, (z,t). Systems and methods discussed below may align different measurement sets so that neural operators may be applied.

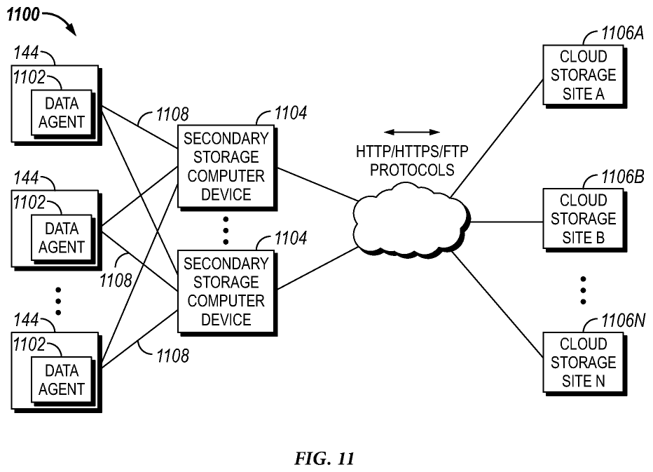

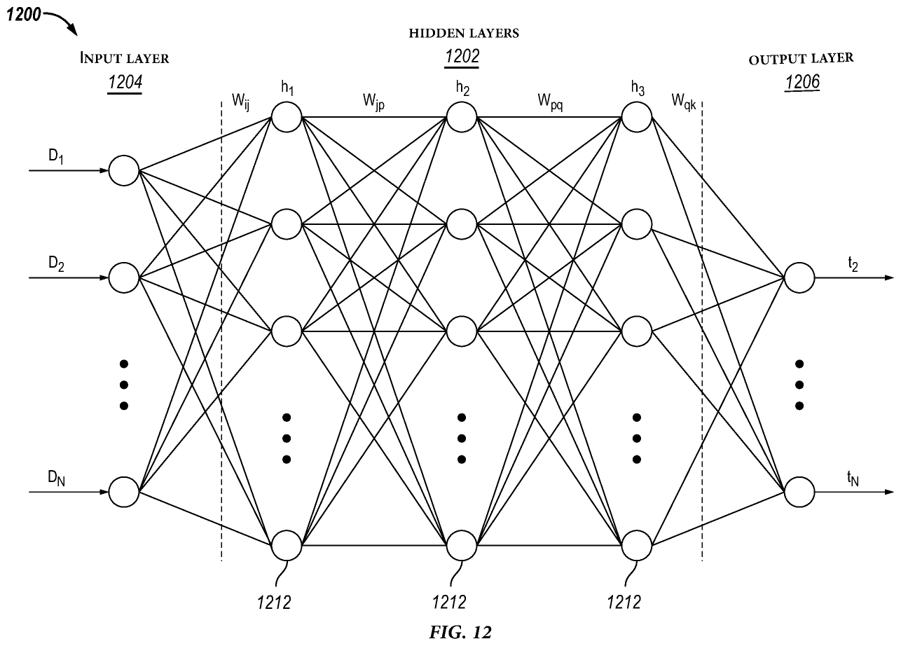

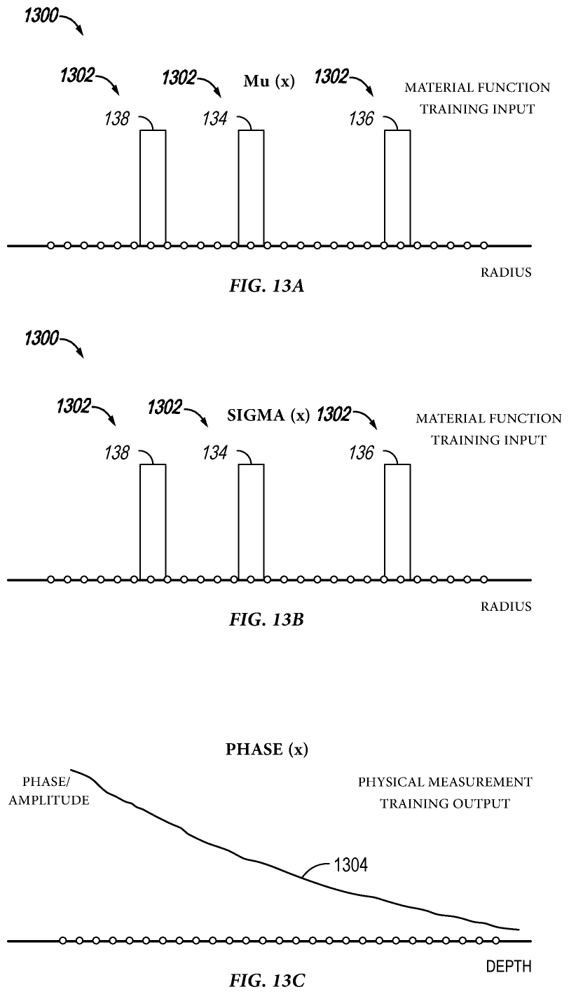

FIGS. 13A-13C illustrate treating the radius direction, herein defined as material function a(r) and depth direction, herein defined as physical response u(z) aligned along the same axis x. With continued refence to FIGS. 13A and 13B, FIG. 13A represents Mu(x) magnetic permeability of material function a(r). FIG. 13B represents Sigma(x) electrical conductivity of material function a(r). As illustrated, magnetic permeability Mu(x) and electrical conductivity Sigma(x) are both components of material function a(r) and may be measured along the radius of wellbore 102 (e.g., referring to FIG. 1).

Material function 1300 may be defined as material function a(r) that may be two or more material properties such as magnetic permeability Mu(x) and electrical conductivity Sigma(x). Spikes 1302 may indicate magnetic permeability or electrical conductivity from pipe string 138, first casing 134, and second casing 136. Further, Phase(x) represents EM measurements from near field 408, transition zone 410, and far field 412 along the depth of wellbore 102. Phase(x) may be represented as the phase and or amplitude response from near field 408, transition zone 410, and far field 412. In examples, amplitude and phase may be combined.

FIG. 13C illustrates Phase(x), physical response 1304. Physical response 1304 may be defined as physical response u(z). Physical response 1304 represents combined phase and amplitude, to be discussed below, of EM measurements from near field 408, transition zone 410, and far field 412 (e.g., referring to FIG. 4A) may be measured across wellbore 102 (e.g., referring to FIG. 1) along the depth direction. However, physical response u(z) may be aligned along the x axis for EM measurements from near field 408, transition zone 410, and far field 412. Thus, magnetic permeability Mu(x), electrical conductivity Sigma(x), and combined phase and amplitude Phase(x) may be aligned on the x axis.

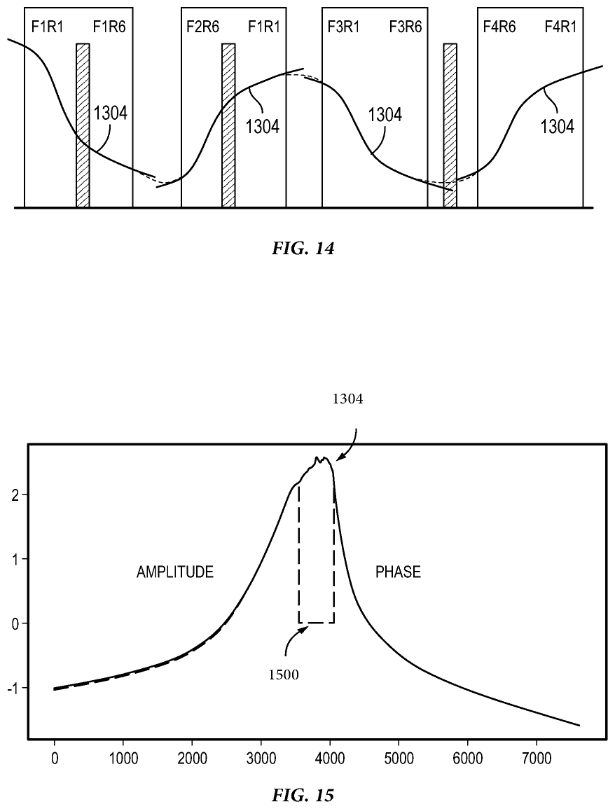

FIG. 14 illustrates an example physical response u(z) with combined phase and amplitude (i.e., identified as physical responses 1304 in FIG. 14). Traditionally, phase and amplitude may be predicted by separate functions, to reduce computation time they may be combined. With further reference to FIG. 14, four separate frequency ranges, within each frequency range an amplitude and a phase may be combined. The four frequency ranges may be identified as F1R1-F1R6, F2R6-F1R1, F3R1-F3R6, and F4R6-F4R1. Each range may be between 0.1-1000 Hz and identify at least one combined phase and amplitude value for each range. In examples, more than four frequency ranges may be used to form a physical response 1304.

FIG. 15 illustrates an example of a formed physical responses 1304. As previously described, predicting the amplitude and phase simultaneously may reduce computation time. The left side of FIG. 15 illustrates amplitude and right side illustrates phase of physical responses 1304. The amplitude and phase may be combined within at least one frequency range 1500. Herein, the x-axis represents frequency in Hz and the y-axis represents a shared amplitude and phase variable in amps. FIG. 15 describes combining measurements for EM applications. However, methods and systems for acoustic applications may also be performed.

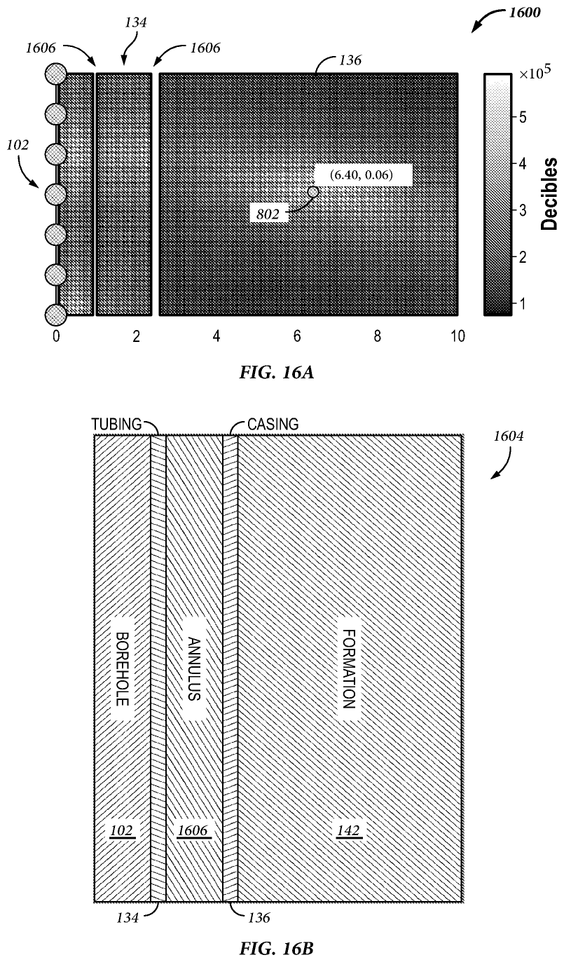

FIG. 16A illustrates traditional beamforming results with a reflected acoustic wave 800 with hydrophones 706 (e.g., referring to FIG. 8). In traditional methods, reflected acoustic wave 800 may be utilized in beamforming to produce beamforming map 1600. Beamforming map 1600 may find leak source 802 with a velocity model v(x,z) 1604. In examples, beamforming may be defined as receiving a reflected acoustic wave 800 as a function of amplitude and time, and outputting beamforming map 1600 as a 2-dimensional spatial image in the x-y plane. FIG. 16B illustrates velocity model v(x,z) 1604, each layer comprises a single velocity value. As illustrated, there may be a consistent acoustic velocity within each layer. Further, one or more annuluses 1606 may be included. In examples, one or more annuli may have similar or different acoustic velocities. Traditionally, beamforming requires the layered velocity model as an input. Additionally, neural operators may require velocity model 1604 as an input as well. However, methods and systems described herein may invert the leak source location and velocity model 1604 simultaneously. As such, FNO may output velocity model 1604 if the velocity is defined as a training output during training stage, to be discussed below.

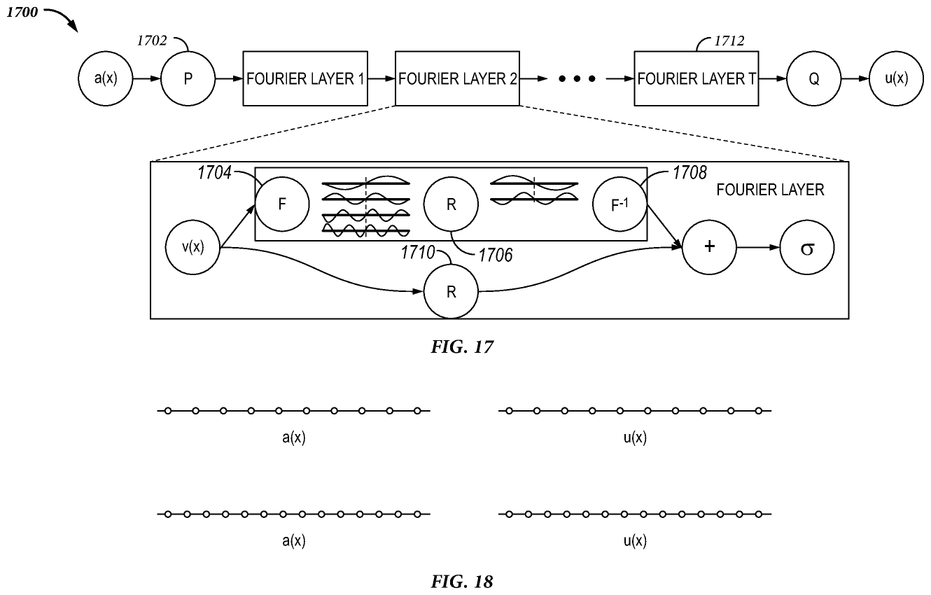

FIG. 17 illustrates an FNO or PINO operator 1700. Herein FNO and PINO are different operations, to be discussed below, but both may be classified as a neural operator. Further as previously stated, material function a(r) represents EM measurements from near field 408, transition zone 410, and far field 412 (e.g., referring to FIG. 4B) along the radial axis. As discussed below, during normalization methods, a(r) may be normalized to a(x) to convert material function from the radial axis to the x axis resulting in material function a(x). As illustrated mapping the material function a(x) to high dimension data by a neural network P may be performed in block 1702. From material function a(x), x denotes the spatial domain over which the material function is defined. In examples, x may be 1-D, 2-D or 3-D domain. 1-D x is along wellbore 102 (e.g., referring to FIG. 1), 2-D x is in (xy) plane, and 3-D x is in (x,y,z) space. In examples material function a(x) may be illustrated in a 1-D, a 2-D or a 3-D dimension such as resistivity (1-D), or permittivity and permeability (2-D), or resistivity, permittivity and permeability (3-D). The number of input channels to neural network P may be as many dimension of material function a(x). For example, if the material function a(x) is a 1-D value defined in 2-D space, such as single resistivity value defined in x-y space, the input channels are 3-D, (value of a, value of x, and value of y). Each channel comprises of (Nx,Ny) pixels. If material function a(x) is a 3-D material value (resistivity, permittivity and permeability) defined in 3-D space (x,y,z).

Block 1704 may perform a Fourier Transform for each input channel of uplifted high dimension input data. Herein, each input channel may be defined as individual Nx-Ny, if x is 2D (x,y) images. Each input channel may process in parallel inside the FNO layers. The Fourier Transform may perform on Nx-Ny grid, in other words, it may follow x definition in material function a(x). After the Fourier Transform, each input channel may be mapped to the kernel R in frequency domain in block 1706, equivalent to Win block 1710 the special domain. Kernel R is a neural kernel inside a neural operator and may map the material to its physical response in a frequency domain. Kernel R is a global kernel in a time domain since the basis function in a Fourier Transform is a global function. Block 1708 performs an inverse Fourier Transform. In examples, blocks 1704, 1706, and 1708 may be combined into block 1710. Blocks 1704, 1706, and 1708 or alternatively block 1710 may be performed for a sufficient number of Fourier Tlayers.

Herein, a sufficient number of Fourier T layers may be defined as the number of Fourier T layers within a threshold of at least 95% of a target goal. The target goal may be numerically tested and verified. In examples, a sufficient number of Fourier T layers may be adjusted to a predetermined number. Block 1712 may map the high dimension to its original dimension. The output of FNO or PINO operator 1700 may be defined as physical response u(x). FNO or PINO operator 1700 is an operator approximation and may map an input function to another function. If during the training, PDE equation is used for error function calculation. FNO and PINO have similar structures. The only difference is that PINO uses PDE equation to evaluate the FNO network by inputting material function a(x) and predicted physical response to PDE equation to substituting the original cost function, which may be defined by predicted response and numerical forward modeling difference. Thus, the training grid size x and prediction grid size x may be different.

Additionally, neural operators may require that there are the same number of points sampled in material function a(x) and physical response u(x). However, material function a(x) and physical response u(x) are not the same in wellbore logging scenarios. This is because the material functions 1300 (e.g., referring to FIG. 13) are along a radius direction and EM measurements from near field 408, transition zone 410, and far field 412 (e.g., referring to FIG. 4B) are along a depth direction. To apply FNO and PINO operations, the FNO or PINO operator may be trained to learn that the radius direction and depth direction are the same. Further, the sampling in radius and depth may also be the same (i.e., there may be the same number of sampling points). Thus, a neural operator may be employed with wellbore logging. A 2D physical model may be changed to a 1D issue, mapping material function a(r) to physical response u(z), as previously described.

FIG. 18 illustrates coarse grids for material function a(x) and physical response u(x) on the top rows and dense girds for material function a(x) and physical response u(x) on the bottom rows. Coarse grids may be used along the x-axis with less points. Once trained, dense grid may be used to satisfy the neural operator requirement of the same number of points sampled in material function a(x) and physical response u(x). As such, the material function a(x) and physical response u(x) may use a dense grid.

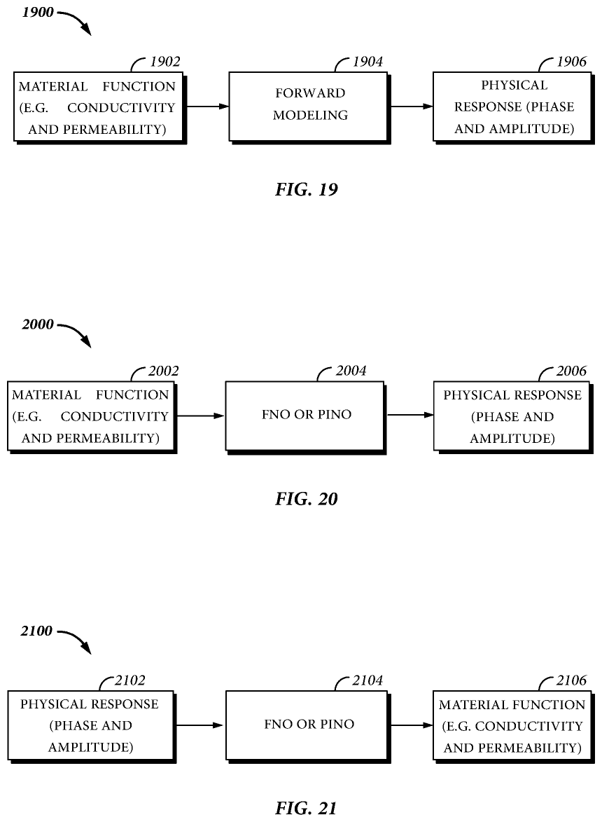

FIG. 19 illustrates workflow 1900, a traditional (partial differential equation) PDE numerical forward modeling to map material function a(r) (i.e., conductivity and permeability) to physical response u(z) (i.e., phase and amplitude). Workflow 1900 may be performed and/or processed on information handling system 144 (e.g., referring to FIG. 1). In workflow 1900, EM measurements from near field 408, transition zone 410, and far field 412 (e.g., referring to FIG. 4B) may be input in block 1902 as material function a(r). Forward modeling may be performed on the input in block 1902 at block 1904. In a traditional inversion workflow, the inversion is repeatedly run and then compared with the forward modelling result that utilized actual measurements. If the error is small, the material properties may be an output, as an inversion result. If the error is large, the inversion algorithm may adjust based on forward modeling performed in block 1904. The forward modeling from block 1904 produces physical response u(z) in the form of phase and amplitude as shown in block 1906. Additionally, blocks 1902 and 1906 may be flipped, allowing a forward model to solve for a material given physical response u(z) input using forward modeling from block 1904. In other examples a neural operator may be substituted for the traditional PDE numerical forward modeling to map the material (i.e., conductivity and permeability) to an EM measurement (i.e., phase and amplitude).

For example, FIG. 20 illustrates workflow 2000, an FNO or PINO substitution of the forward modeling to map material function a(r) (i.e., conductivity and permeability) to physical response u(z) (i.e., phase and amplitude). Workflow 2000 may be performed and/or processed on information handling system 144 (e.g., referring to FIG. 1). In workflow 2000, EM measurements from near field 408, transition zone 410, and far field 412 (e.g., referring to FIG. 4B) may be input in block 2002. Due to the physical constraint of the measurements within the wellbore 102 (e.g., referring to FIG. 1), the actual configuration may not meet with FNO/PINO application requirement, as previously described. Thus, FNO or PINO may not be used directly in those physical response. In some cases, even though the FNO or PINO neural operator may not be directly utilized, as it is not the most efficient and effective way. For example, modifying the FNO or PINO structure to extend its usage if the original condition does not meet with FNO or PINO application requirement. In workflow 2000, near field 408, transition zone 410, and far field 412 (e.g., referring to FIG. 4B) may be in block 2002 material function a(r). Block 2004 performs FNO or PINO operator 1700 (e.g., referring to FIG. 17) on material function a(r) to produce physical response u(z) for block 2006. However, material function a(r) and physical response u(z) may be flipped.

For example, FIG. 21 illustrates workflow 2100, a FNO or PINO substituting the forward modeling to map physical response u(z) (i.e., phase and amplitude) to material function a(r) (i.e., conductivity and permeability). Workflow 2100 may be performed and/or processed on information handling system 144 (e.g., referring to FIG. 1). In workflow 1900, EM measurements from near field 408, transition zone 410, and far field 412 (e.g., referring to FIG. 4B) may be input in block 2102 as physical response u(z). By assuming the material function a(r) equivalent with physical response u(z), this may allow for mapping physical response u(z) to material function a(r). Block 2104 performs FNO or PINO operator 1700 (e.g., referring to FIG. 17) on physical response u(z) to produce material function a(r) for block 2106. Workflows 2000 (e.g., referring to FIG. 20) and 2100 are general concepts and may be considered when developing more detailed workflows. More detailed workflows incorporating neural operators may be performed on information handling system 144 (e.g., referring to FIG. 1) as described below. In examples, a neural operator may be applied with EM implementations in a more detailed workflow, as described above.

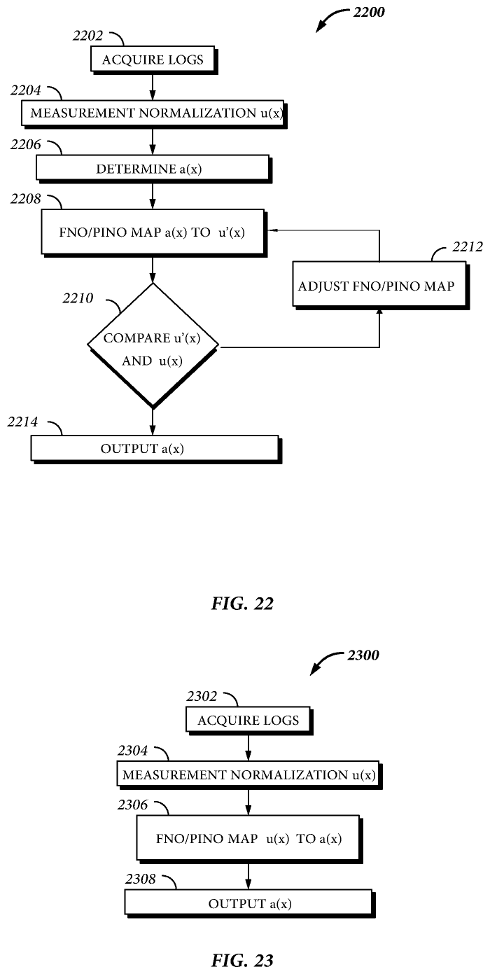

FIG. 22 illustrates workflow 2200, a proposed FNO or PINO inversion for pipe inspection. Workflow 2200 may be performed and/or processed on information handling system 144 (e.g., referring to FIG. 1). In block 2202 EM measurements from near field 408, transition zone 410, and far field 412 (e.g., referring to FIG. 4B) may be acquired as a log, as described above. In examples, block 2202 may acquire material function a(r) or physical response u(z). In Block 2204 normalization for the measurements may be performed on the log to produce normalized physical response u(x). As illustrated, block 2204 performs a measurement normalization on physical response u(z). Measurement normalization may be defined as assimilating each log from block 2202 to have the same number of sampled points and are along the same axis, as previously described. Block 2206 performs forward modeling 1904 (e.g., referring to FIG. 19) with normalized physical response u(x) to produce a normalized material function a(x). In examples, the sampling points of normalized material function a(x) may be the same as normalized physical response u(x), as described in block 1704 (e.g., referring to FIG. 17), with a trained FNO or PINO. Block 2208 implements blocks 1706 and 1708 and 1712 to map normalized material function a(x) to yield a u′(x). In block 2210 normalized physical response u(x) from block 2206 and neural operator generated physical response u′(x) from block 2208 may be compared. In the comparison, the difference between every sampled point from physical response u(x) and every corresponding sampled point from neural operator generated physical response u′(x) may be determined and separately input into a difference matrix. As the result, the difference matrix may comprise a number of sampled points equal to the number of sampled points in both physical response u(x) and neural operator generated physical response u′(x). Herein, the number of sampled points may be referred to as n points. An accuracy index is calculated by summing every difference within the difference matrix and dividing the summation by n points to produce a quotient. The quotient may then be used be multiplied by 100% and used to subtract from 100% to yield an accuracy index. The accuracy index may be further considered to a threshold.

With continued reference to block 2210, a threshold may be manually selected and optionally adjusted. Examples of a threshold may range between 50%-90%, 90%-99%, or 99%-99.9%, or the like. If the accuracy index is less than the threshold, block 2212 adjusts the neural operator in block 2208 and blocks 2208 and 2210 are repeated with the adjusted neural operator. Herein, adjusting the neural operator may be an iterative process. In examples, it may only be adjusted by 5% or less for every sampled point in every iteration until an acceptable threshold is achieved. Additionally, a threshold may require an adjustable input. However, if the average of the data set is within a threshold, the material function a(x) is output at block 2214. Additionally, the neural operator from block 2208 may be accepted as a valid neural operator for future operations once the accuracy index is within the threshold. Workflow 2200 is a detailed workflow which outputs material function a(x), however a more general workflow which also produces a material function a(x) may be implemented.

A more general approach to FNO or PINO neural operations may be applied with EM implementation. FIG. 23 outlines a workflow 2300, a proposed simplified FNO or PINO inversion for pipe inspection. Workflow 2300 may be performed and/or processed on information handling system 144 (e.g., referring to FIG. 1). Block 2302 acquires logs as performed in block 2202 (e.g., referring to FIG. 22). Block 2304 data performs normalization for the measurement to produce normalized physical response u(x) as in block 2204 (e.g., referring to FIG. 22). Block 2306 is performed, similar to blocks 1704, 1706, and 1708 (e.g., referring to FIG. 17) to produce material function a(x). Block 2308 outputs material function a(x). FIGS. 19-23 work through the process of a traditional PDE numerical forward modeling and its replacement for neural operators utilizing EM measurements. However, acoustic measurements may be considered as well.

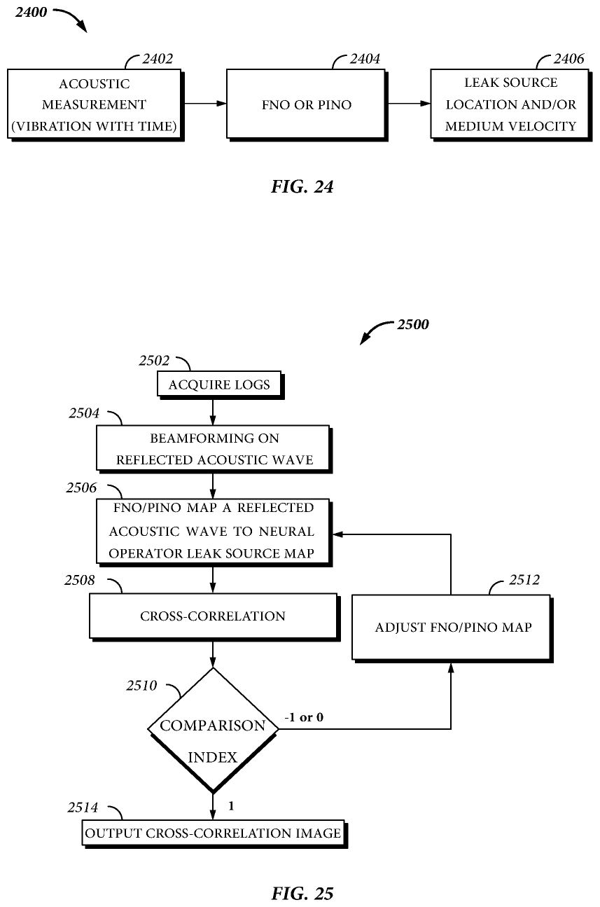

For example, FIG. 24 illustrates workflow 2400, a FNO or PINO substitution for beamforming map 1600 (e.g., referring to FIG. 16) to map reflected acoustic wave 800 (e.g., referring to FIG. 8) to a leak source 802. Workflow 2300 may be performed and/or processed on information handling system 144 (e.g., referring to FIG. 1). Workflow 2400 may input reflected acoustic wave 800 to block 2202. FNO or PINO operator 1700 is performed at block 2204, which may produce leak source 802 estimation location and/or the velocity model 1604 (e.g., referring to FIG. 16). Therefore, the FNO or PINO operator 1700 from block 2404 receives a reflected acoustic wave 800 as a function of amplitude and time, and outputs leak source 802 as a 2-dimensional spatial image in the x-y plane, similar to beamforming map 1600. Workflow 2400 is a general concept and may be considered when developing more detailed workflows. More detailed workflows incorporating neural operators may be performed on information handling system 144 (e.g., referring to FIG. 1).

In other examples, a neural operator may be applied to acoustic measurements. FIG. 25 illustrates workflow 2500, a proposed FNO or PINO inversion with a known velocity model 1604 (e.g., referring to FIG. 16) for leak source location. Workflow 2500 may be performed and/or processed on information handling system 144 (e.g., referring to FIG. 1). In block 2502 a reflected acoustic wave 800 (e.g., referring to FIG. 8) is acquired as a log, as described above. Block 2504 performs beamforming to produce a beamforming map 1600 using velocity model 1604. Block 2506 implements blocks 1706 and 1708 and 1712 (e.g., referring to FIG. 17) to map a reflected acoustic wave 800 with velocity model 1604 to produce a neural operator leak source location map. Block 2508 cross-correlates the neural operator leak source location map from block 2506 with beamforming map 1600 from block 2504. Block 2508 perform a cross-correlation. Herein a cross correlation is a mathematical operation, which extracts the similarity between two functions or two images and outputs a comparison index. The comparison index may be 1 representing the same image or function, −1 represents the same image or function but with a different sign, or 0 representing the two functions or images are irrelevant. Block 2510 may make a decision based on the comparison index. If there is insufficient cross correlation (i.e., the cross correlation from block 2508 yields a comparison index of 0 or −1), block 2512 adjusts the neural operator from block 2506. Blocks 2506 and 2508 may be repeated until there is appropriate cross correlation (i.e., comparison index of 1). Herein, adjusting neural operator may be an iterative process. In examples, it may only be adjusted by 5% or less for every sampled point in every iteration until an acceptable threshold is achieved. The resulting neural operator leak source location map may be output at block 2516. Additionally, the neural operator from block 2506 may be accepted as a valid neural operator for future operations once there is a cross correlation in block 2508. Workflow 2500 is performed with a known velocity model 1604 (e.g., referring to FIG. 16). However, in other examples, velocity model 1604 may not be known.

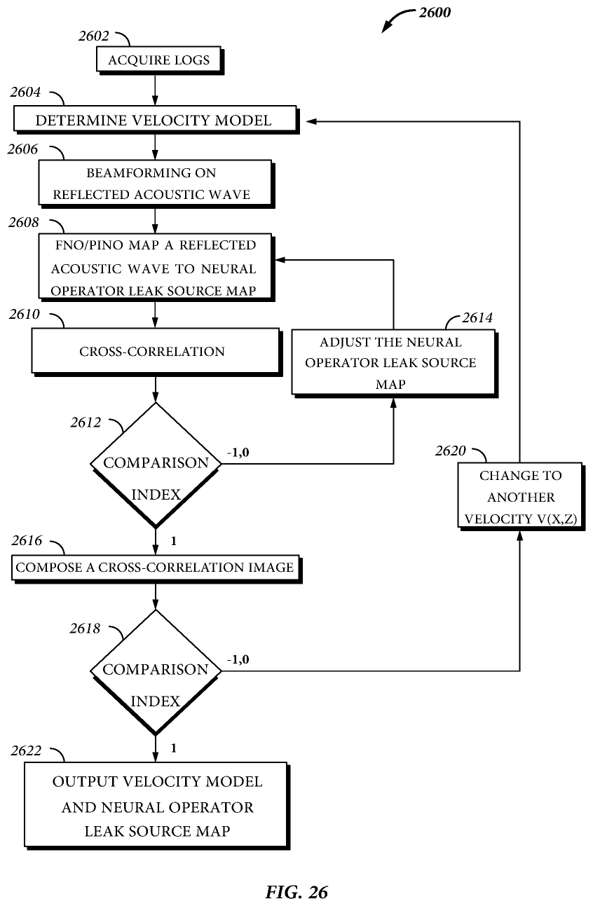

Acoustic implementation of neural operators may still be possible even if velocity model 1604 (e.g., referring to FIG. 16) is not provided. For example, FIG. 26 illustrates workflow 2600, a proposed FNO or PINO inversion for leak source location without a known velocity model 1604. Workflow 2600 may be performed and/or processed on information handling system 144 (e.g., referring to FIG. 1). Block 2602 a reflected acoustic wave 800 (e.g., referring to FIG. 8) is acquired as a log, as described above. In block 2604, a velocity model is determined. Velocity model 1604 may be determined using historical well information. Block 2606 performs beamforming to produce a beamforming map 1600 using velocity model 1604. Block 2608 implements blocks 1706, 1708, and 1712 (e.g., referring to FIG. 17) to map a reflected acoustic wave 800 with the determined velocity model 1604 to produce a neural operator leak source location map. Block 2610 performs a cross correlation between the neural operator leak source location map from block 2608 with beamforming map 1600 from block 2606, as previously described to produce a comparison index. Block 2612 may make a decision based on the comparison index. If the comparison index is a −1 or 0, block 2614 adjusts the neural operator. Then, blocks 2608 and 2610 may be repeated until there is appropriate cross correlation. Herein, adjusting neural operator may be an iterative process. In examples, it may be adjusted by 5% or less for every sampled point in every iteration until an acceptable threshold is achieved. If the comparison index from block 2610 is 1, the resulting neural operator leak source location map may be composed at block 2616. Herein, composing may be defined as using traditional inversion and forward modeling techniques to determine a velocity model 1604 with neural operator leak source location map. Block 2618 performs a cross correlation by producing a comparison index as described above between the velocity model 1604 from block 2616 and the velocity model 1604 from block 2604. Block 2620 may update the previously assumed velocity model 1604 to be incremented if the comparison index from block 2618 is a −1 or 0 and then repeating blocks 2604-2616. Thus, sweeping a range of values for velocity model 1604. However, if the comparison index from block 2618 is a 1, block 2622 outputs the final velocity model 1604 and neural operator leak source location map. Additionally, the neural operator from block 2608 may be accepted as a valid neural operator for future operations once there is a cross correlation in block 2618. Workflow 2500 (e.g., referring to FIG. 25) and workflow 2600 are detailed workflows which output at least a cross correlated image yielding leak source 802, however a more general workflow which also yields least a cross correlated image yielding leak source 802 may be implemented.

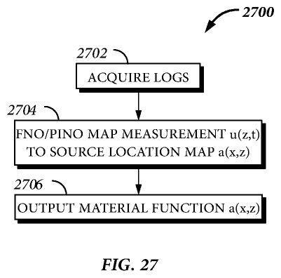

A more general approach to FINO or PINO neural operations may be applied with acoustic implementation. FIG. 27 illustrates a workflow 2700, a proposed simplified FNO or PINO inversion for leak source location. Workflow 2700 may be performed and/or processed on information handling system 144 (e.g., referring to FIG. 1). Block 2702 acquires logs as performed in block 2502 (e.g., referring to FIG. 25). Block 2704 is performed, similar to blocks 1704, 1706, and 1708 to a source location map. In block 2706, the source location map if formed as an output.

Currently, inversion algorithms and beamforming are the primary implementation standard in the art. However, when determining pipe properties inversion algorithms fall short of efficiently solving for pipe status parameters even with using a simplified radial 1-D model. Similarly, beamforming algorithms may also fall short for efficiently solving for leak location parameters in 2-D, even with using high-performance computing or GPUs. The methods and systems discussed above are an improvement over current technology. Specifically, the methods and systems utilized above may implement a neural operator such as FNO or PINO to substitute the numerical forward modelling, update inputted functions of material function a(x) or physical response u(x) to align on the same axis, or change the leak source measurements from time domain to spatial domain. Finally, all measurements may be merged into a single function to minimize running time.

The systems and methods may include any of the various features disclosed herein, including one or more of the following statements.

Statement 1: A method may comprise obtaining one or more measurements, performing a measurement normalization on the one or more measurements to form one or more normalized measurements, forming a material function with the one or more normalized measurements, and forming a neural operator generated physical response with a neural operator and the material function.

Statement 2: The method of statement 1, wherein the neural operator is a Fourier Neural Operator (FNO) or a Physics-Informed Neural Operator (PINO).

Statement 3: The method of any preceding statements 1 or 2, wherein the one or more measurements are electromagnetic (EM) measurements from a near field, a transition zone, and a far field.

Statement 4: The method of any preceding statements 1, 2, or 3, further comprising forming an accuracy index with the neural operator generated physical response and the one or more normalized measurements.

Statement 5: The method of statement 4 further comprising comparing the accuracy index to a threshold.

Statement 6: The method of statement 5, further comprising accepting the neural operator if the accuracy index is greater than the threshold.

Statement 7: The method of statement 5, further comprising adjusting the material function if the neural operator is below the threshold.

Statement 8: A method may comprise obtaining one or more measurements, forming a beamforming map with the one or more measurements, and forming a neural operator leak source location map with a neural operator and the one or more measurements.

Statement 9: The method of statement 8, wherein the neural operator is a Fourier Neural Operator (FNO) or a physics-Informed Neural Operator (PINO).

Statement 10: The method of any preceding statements 8 or 9, wherein the one or more measurements are a reflected acoustic wave.

Statement 11: The method of statement 10, further performing a cross correlation with at least the beamforming map and the neural operator leak source location map.

Statement 12: The method of statement 11, wherein a cross correlation forms a comparison index.

Statement 13: The method of statement 12, further comprising accepting the neural operator if the comparison index is 1.

Statement 14: The method of statement 12, further comprising adjusting the neural operator if the comparison index is −1 or 0.

Statement 15: A non-transitory storage computer-readable medium storing one or more instructions that, when executed by a processor, may cause the processor to perform a measurement normalization on one or more measurements to form one or more normalized measurements, form a material function with the one or more normalized measurements, and form a neural operator generated physical response with a neural operator and the material function.

Statement 16: The non-transitory storage computer-readable medium of statement 15, wherein the neural operator is a Fourier Neural Operator (FNO) or a Physics-Informed Neural Operator (PINO).

Statement 17: The non-transitory storage computer-readable medium of any preceding statements 15 or 16, wherein the one or more measurements are electromagnetic (EM) from a near field, a transition zone, and a far field.

Statement 18: The non-transitory storage computer-readable medium of any preceding statements 15, 16, or 17, wherein the one or more instructions, that when executed by the processor, further cause the processor to form an accuracy index with the neural operator generated physical response and the one or more normalized measurements, and compare the accuracy index to a threshold.

Statement 19: The non-transitory storage computer-readable medium of statement 18, wherein the one or more instructions, that when executed by the processor, further cause the processor to accept the neural operator if the accuracy index is greater than the threshold.

Statement 20: The non-transitory storage computer-readable medium of statement 18, wherein the one or more instructions, that when executed by the processor, further cause the processor to adjust the material function if the neural operator is below the threshold.

The preceding description provides various embodiments of the systems and methods of use disclosed herein which may contain different method blocks and alternative combinations of components. It should be understood that, although individual embodiments may be discussed herein, the present disclosure covers all combinations of the disclosed embodiments, including, without limitation, the different component combinations, method block combinations, and properties of the system. It should be understood that the compositions and methods are described in terms of “including,” “containing,” or “including” various components or blocks, the compositions and methods can also “consist essentially of” or “consist of” the various components and blocks. Moreover, the indefinite articles “a” or “an,” as used in the claims, are defined herein to mean one or more than one of the element that it introduces.

For the sake of brevity, only certain ranges are explicitly disclosed herein. However, ranges from any lower limit may be combined with any upper limit to recite a range not explicitly recited, as well as ranges from any lower limit may be combined with any other lower limit to recite a range not explicitly recited, in the same way, ranges from any upper limit may be combined with any other upper limit to recite a range not explicitly recited. Additionally, whenever a numerical range with a lower limit and an upper limit is disclosed, any number and any included range falling within the range are specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values even if not explicitly recited. Thus, every point or individual value may serve as its own lower or upper limit combined with any other point or individual value or any other lower or upper limit, to recite a range not explicitly recited.

Therefore, the present embodiments are well adapted to attain the ends and advantages mentioned as well as those that are inherent therein. The particular embodiments disclosed above are illustrative only and may be modified and practiced in different but equivalent manners apparent to those skilled in the art having the benefit of the teachings herein. Although individual embodiments are discussed, the disclosure covers all combinations of all of the embodiments. Furthermore, no limitations are intended to the details of construction or design herein shown, other than as described in the claims below. Also, the terms in the claims have their plain, ordinary meaning unless otherwise explicitly and clearly defined by the patentee. It is therefore evident that the particular illustrative embodiments disclosed above may be altered or modified and all such variations are considered within the scope and spirit of those embodiments. If there is any conflict in the usages of a word or term in this specification and one or more patent(s) or other documents that may be incorporated herein by reference, the definitions that are consistent with this specification should be adopted.

What is claimed is:

1. A method comprising:
obtaining one or more measurements;
performing a measurement normalization on the one or more measurements to form one or more normalized measurements;
forming a material function with the one or more normalized measurements; and
forming a neural operator generated physical response with a neural operator and the material function.

2. The method of claim 1, wherein the neural operator is a Fourier Neural Operator (FNO) or a Physics-Informed Neural Operator (PINO).

3. The method of claim 1, wherein the one or more measurements are electromagnetic (EM) measurements from a near field, a transition zone, and a far field.

4. The method of claim 1, further comprising forming an accuracy index with the neural operator generated physical response and the one or more normalized measurements.

5. The method of claim 4, further comprising comparing the accuracy index to a threshold.

6. The method of claim 5, further comprising accepting the neural operator if the accuracy index is greater than the threshold.

7. The method of claim 5, further comprising adjusting the material function if the neural operator is below the threshold.

8. A method comprising:
obtaining one or more measurements;
forming a beamforming map with the one or more measurements; and
forming a neural operator leak source location map with a neural operator and the one or more measurements.

9. The method of claim 8, wherein the neural operator is a Fourier Neural Operator (FNO) or a physics-Informed Neural Operator (PINO).

10. The method of claim 8, wherein the one or more measurements are a reflected acoustic wave.

11. The method of claim 10, further performing a cross correlation with at least the beamforming map and the neural operator leak source location map.

12. The method of claim 11, wherein a cross correlation forms a comparison index.

13. The method of claim 12, further comprising accepting the neural operator if the comparison index is 1.

14. The method of claim 12, further comprising adjusting the neural operator if the comparison index is −1 or 0.

15. A non-transitory storage computer-readable medium storing one or more instructions that, when executed by a processor, cause the processor to:
perform a measurement normalization on one or more measurements to form one or more normalized measurements;
form a material function with the one or more normalized measurements; and
form a neural operator generated physical response with a neural operator and the material function.

16. The non-transitory storage computer-readable medium of claim 15, wherein the neural operator is a Fourier Neural Operator (FNO) or a Physics-Informed Neural Operator (PINO).

17. The non-transitory storage computer-readable medium of claim 15, wherein the one or more measurements are electromagnetic (EM) from a near field, a transition zone, and a far field.

18. The non-transitory storage computer-readable medium of claim 15, wherein the one or more instructions, that when executed by the processor, further cause the processor to:
form an accuracy index with the neural operator generated physical response and the one or more normalized measurements; and
compare the accuracy index to a threshold.

19. The non-transitory storage computer-readable medium of claim 18, wherein the one or more instructions, that when executed by the processor, further cause the processor to accept the neural operator if the accuracy index is greater than the threshold.

20. The non-transitory storage computer-readable medium of claim 18, wherein the one or more instructions, that when executed by the processor, further cause the processor to adjust the material function if the neural operator is below the threshold.
